(19) United States
(12) Patent Application Publication
(10) Pub. No.: US 2026/0013300 A1
(43) Pub. Date: Jan. 8, 2026

(54) DISPLAY PANEL AND ELECTRONIC DEVICE INCLUDING THE DISPLAY PANEL

(71) Applicant: Samsung Display Co., LTD., Yongin-si (KR)

(72) Inventors: Dongmin Lee, Yongin-si (KR); Joonyong Park, Yongin-si (KR); Hyuneok Shin, Yongin-si (KR); Sukyoung Yang, Yongin-si (KR)

(21) Appl. No.: 19/259,968

(22) Filed: Jul. 3, 2025

(30) Foreign Application Priority Data
Jul. 5, 2024 (KR) 10-2024-0089112

(51) Int. Cl. H10H 29/49; H01L 25/075; H10H 29/32; H10H 29/37; H10H 29/39; H10H 29/854

(52) U.S. Cl. CPC H10H 29/49; H01L 25/0753; H10H 29/32; H10H 29/37; H10H 29/39; H10H 29/854

(57) ABSTRACT

A display panel includes a substrate, a pixel circuit layer disposed on the substrate and including a transistor, a common electrode disposed on the pixel circuit layer, a conductive partition wall including a first partition wall layer disposed on the common electrode and a second partition wall layer disposed on the first partition wall layer, the conductive partition wall being electrically connected to the common electrode, a partition wall insulation layer disposed on the conductive partition wall, and a light-emitting element including a pixel electrode disposed on the partition wall insulation layer and electrically connected to the transistor, an intermediate layer disposed on the pixel electrode and including an emission layer, and a counter electrode disposed on the intermediate layer and electrically connected to the conductive partition wall, wherein the first partition wall layer includes an aluminum alloy.

This application claims priority to Korean Patent Application No. 10-2024-0089112, filed on Jul. 5, 2024, and all the benefits accruing therefrom under 35 U.S.C. § 119, the content of which in its entirety is herein incorporated by reference.

### BACKGROUND

### 1. Field

Embodiments relate to a display panel and an electronic device including the same.

### 2. Description of the Related Art

In recent years, uses of display panels are becoming more diverse. In addition, as the display panels become thinner and lighter, a range of applications for display panels is expanding.

In general, display panels include a plurality of pixels that emit light in response to electrical signals to display an image. The pixels of a display panel each include a light-emitting element as a display element, and the light-emitting element includes a pixel electrode, an emission layer, and a counter electrode.

### SUMMARY

Embodiments include a display panel with improved display quality and a method of manufacturing the same. Embodiments include an electronic device including a display panel with improved display quality. However, the embodiments are examples and do not limit the scope of the disclosure.

Additional features will be set forth in part in the description which follows and, in part, will be apparent from the description, or may be learned by practice of the presented embodiments of the disclosure.

In an embodiment of the disclosure, a display panel includes a substrate, a pixel circuit layer disposed on the substrate and including a transistor, a common electrode disposed on the pixel circuit layer, a conductive partition wall including a first partition wall layer disposed on the common electrode and a second partition wall layer disposed on the first partition wall layer, the conductive partition wall being electrically connected to the common electrode, a partition wall insulation layer disposed on the conductive partition wall, and a light-emitting element including a pixel electrode disposed on the partition wall insulation layer and electrically connected to the transistor, an intermediate layer disposed on the pixel electrode and including an emission layer, and a counter electrode disposed on the intermediate layer and electrically connected to the conductive partition wall, wherein the first partition wall layer may include an aluminum alloy.

In an embodiment, the aluminum alloy may include aluminum (Al) as a main component and further include at least one impurity metal selected from nickel (Ni), lanthanum (La), neodymium (Nd), or germanium (Ge).

In an embodiment, in a state in which the at least one impurity metal is a singular impurity metal, an atomic ratio of the at least one impurity metal may be in a range of about 0.06 atomic percent to about 1 atomic percent based on total atoms in the aluminum alloy, and in a state in which the at least one impurity metal is provided in plural, a sum of respective atomic ratios of a plurality of impurity metals included in the aluminum alloy may be in the range of about 0.06 atomic percent to about 1 atomic percent based on total atoms in the aluminum alloy.

In an embodiment, the first partition wall layer may include an aluminum-nickel-lanthanum alloy (Al—Ni—La alloy).

In an embodiment, a sum of an atomic ratios of nickel (Ni) and an atomic ratios of lanthanum (La) in the aluminum-nickel-lanthanum alloy (Al—Ni—La alloy) may be in a range of about 0.06 atomic percent to about 1 atomic percent based on total atoms in the aluminum alloy.

In an embodiment, the second partition wall layer may include a different conductive material from that of the first partition wall layer.

In an embodiment, a width of the second partition wall layer in a first direction may be greater than a width of the first partition wall layer in the first direction.

In an embodiment, the display panel may further include a pixel defining layer which is disposed on the partition wall insulation layer and in which a pixel opening exposing at least a portion of the pixel electrode is defined.

In an embodiment, the conductive partition wall may overlap the pixel opening.

In an embodiment, the intermediate layer may cover a side surface of the second partition wall layer, and the counter electrode may cover an upper surface of the intermediate layer and a side surface of the intermediate layer.

In an embodiment, the display panel may further include an auxiliary electrode covering the counter electrode and electrically connected to the conductive partition wall.

In an embodiment, the auxiliary electrode may cover at least a portion of the conductive partition wall.

In an embodiment, the auxiliary electrode may cover a lower surface of the second partition wall layer.

In an embodiment, the display panel may further include an inorganic encapsulation pattern covering an upper surface of the auxiliary electrode, wherein the inorganic encapsulation pattern may be spaced apart from the common electrode in a cross-sectional view.

In an embodiment, the inorganic encapsulation pattern may have an island-shaped pattern in a plan view.

In an embodiment, a distance from the substrate to the pixel electrode may be greater than a distance from the substrate to the second partition wall layer.

In an embodiment of the disclosure, a display panel includes a conductive partition wall including a first partition wall layer including an aluminum alloy and a second partition wall layer disposed on the first partition wall layer and including a different conductive material from that of the first partition wall layer, a light-emitting element including a pixel electrode disposed on the conductive partition wall and overlapping the conductive partition wall, an intermediate layer disposed on the pixel electrode and including an emission layer, and a counter electrode disposed on the intermediate layer and electrically connected to the conductive partition wall, and a partition wall insulation layer disposed between the conductive partition wall and the light-emitting element, wherein the aluminum alloy included in the first partition wall layer may include aluminum (Al) as a main component and may further include at least one impurity metal selected from nickel (Ni), lanthanum (La), neodymium (Nd), or germanium (Ge).

In an embodiment, in a state in which the at least one impurity metal is a singular impurity metal, an atomic ratio of the at least one impurity metal may be in a range of about 0.06 atomic percent to about 1 atomic percent based on total atoms in the aluminum alloy, and in a state in which the at least one impurity metal is provided in plural, a sum of respective atomic ratios of a plurality of impurity metals included in the aluminum alloy may be in the range of about 0.06 atomic percent to about 1 atomic percent based on total atoms in the aluminum alloy.

In an embodiment, the first partition wall layer may include an aluminum-nickel-lanthanum alloy (Al—Ni—La alloy).

In an embodiment, the display panel may further include an auxiliary electrode covering the counter electrode and electrically connected to the conductive partition wall.

In embodiments, an electronic device includes a display panel, a cover window disposed on the display panel, and a housing accommodating the display panel and including a rear surface and a side surface, wherein the display panel may include a substrate, a pixel circuit layer disposed on the substrate and including a transistor, a common electrode disposed on the pixel circuit layer, a conductive partition wall including a first partition wall layer disposed on the common electrode and a second partition wall layer disposed on the first partition wall layer, the conductive partition wall being electrically connected to the common electrode, a partition wall insulation layer disposed on the conductive partition wall, and a light-emitting element including a pixel electrode disposed on the partition wall insulation layer and electrically connected to the transistor, an intermediate layer disposed on the pixel electrode and including an emission layer, and a counter electrode disposed on the intermediate layer and electrically connected to the conductive partition wall, wherein the first partition wall layer may include an aluminum alloy.

### BRIEF DESCRIPTION OF THE DRAWINGS

The above and other features and advantages of illustrative embodiments of the disclosure will be more apparent from the following description taken in conjunction with the accompanying drawings, in which:

FIG. 1A is a schematic perspective view of an embodiment of an electronic device;

FIG. 1B is an exploded perspective view of an embodiment of an electronic device;

FIG. 2 is a schematic plan view of an embodiment of a display panel;

FIG. 3 is a schematic equivalent circuit diagram of an embodiment of a light-emitting element corresponding to a subpixel of a display panel and a subpixel circuit electrically connected to the light-emitting element;

FIG. 4 is an enlarged plan view of an embodiment of a portion of a display area of a display panel;

FIG. 5 is a schematic cross-sectional view of a section of a display panel, taken along line I-I′ of FIG. 4;

FIG. 6 is a schematic cross-sectional view of a section of a display panel, taken along line II-II′ of FIG. 4;

FIG. 7 is a schematic cross-sectional view of a section of a display panel, taken along line III-III′ of FIG. 4;

FIG. 8 illustrates a set of surface images of aluminum and an aluminum alloy;

FIGS. 9A to 9K are cross-sectional views illustrating an embodiment of a method of manufacturing a display panel, according to an embodiment; and

FIG. 10 is a block diagram illustrating an embodiment of an electronic device.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Embodiments may be modified in various ways and may have various embodiments, and thus, illustrative embodiments are illustrated in the drawings and described in detail in the detailed description. Effects and features of embodiments and methods for achieving the same could become clear by referring to embodiments described in detail below along with the drawings. However, the disclosure is not limited to the embodiments described below and may be implemented in various forms.

Hereinafter, embodiments will be described in detail with reference to the attached drawings. When describing with reference to the drawings, identical or corresponding components are given the same drawing numbers and redundant descriptions thereof are omitted.

In the following embodiments, the terms “first”, “second,” etc. are not used in a limiting sense but are used to distinguish one component from another.

In the following embodiments, a first direction DR1, a second direction DR2, and a third direction DR3 are not limited to three axes on an orthogonal coordinate system, and may be interpreted in a broad sense including the same. For example, the first direction DR1, the second direction DR2, and the third direction DR3 may be orthogonal to each other, but may also refer to different directions that are not orthogonal to each other.

Herein, singular expressions include plural expressions, unless the context clearly dictates otherwise.

In the following embodiments, terms such as “comprise,” “include,” or “have” mean that a feature or component described in the specification is present, and do not exclude the possibility that one or more other features or components may be added.

Herein, when a part of a layer, area, element, or the like is disposed over or on another part, it refers not only to a case where the part is directly on top of the other part, but also a case where another layer, area, element, or the like is located therebetween.

In the drawings, for convenience of description, the sizes of elements may be exaggerated or reduced. For example, the size and thickness of each element shown in the drawings are shown arbitrarily for convenience of description, and thus, one or more embodiments are not necessarily limited to shown.

In some embodiments, in which the implementation is otherwise feasible, specific process sequences may be performed in a different order than described. For example, two processes described in succession may be performed substantially at the same time, or may be performed in an order opposite to that in which they are described.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, or 5% of the stated value, for example.

In the following embodiments, it will be understood that when a layer, an area, or an element, etc. is referred to as being connected to another layer, area, or element, it may be directly or indirectly connected to the other layer, area, or element. For example, it will be understood in this specification that when a layer, an area, or an element is referred to as being in contact with or electrically connected to another layer, area, or element, it may be directly or indirectly in contact with or electrically connected to the other layer, area, or element.

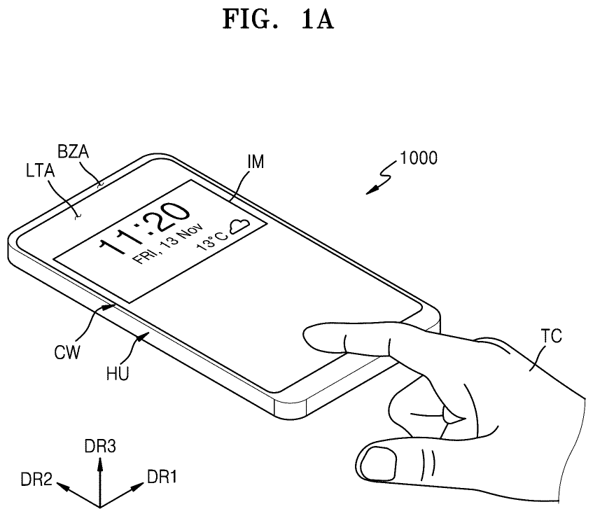

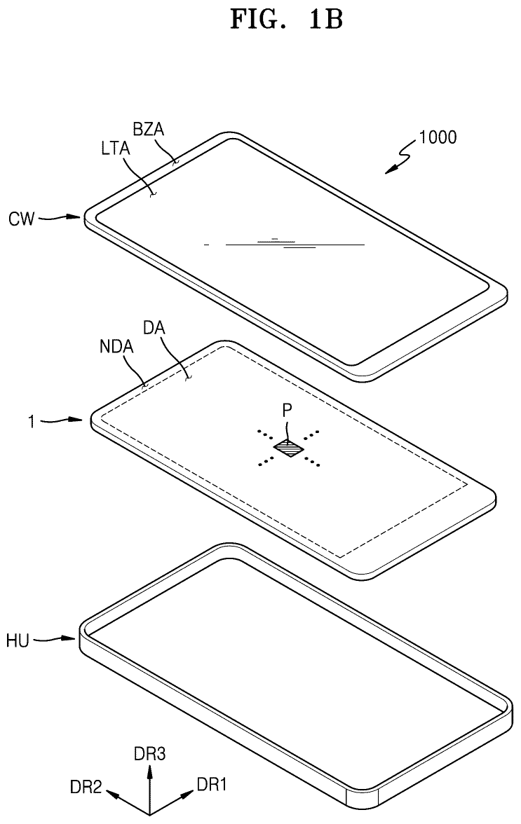

FIG. 1A is a schematic perspective view of an embodiment of an electronic device 1000. FIG. 1B is an exploded perspective view of an embodiment of the electronic device 1000.

In an embodiment, the electronic device 1000 is a device that displays video or still images, and may be used not only as a portable electronic device such as a mobile phone, a smart phone, a tablet personal computer, a mobile communication terminal, an electronic organizer, an electronic book, a portable multimedia player (“PMP”), a navigation device, and an ultra mobile personal computer (“UMPC”), but also as a display screen of various products such as televisions, laptops, monitors, billboards, and Internet of Things (“IoT”) devices. In an embodiment, the electronic device 1000 may also be used in wearable devices such as smart watches, watch phones, glasses-type displays, or head mounted displays (“HMDs”). In an embodiment, the electronic device 1000 may also be used as a dashboard in a vehicle, a center information display (“CID”) of a center fascia or dashboard in a vehicle, a room mirror display that replaces the side mirrors of a vehicle, and a display screen disposed on the rear side of a front seat to serve as an entertainment device for back seat passengers of vehicles.

For convenience of explanation, FIGS. 1A and 1B illustrate an embodiment of the electronic device 1000 as a smart phone.

Referring to FIGS. 1A and 1B, the electronic device 1000 may display an image IM in a third direction (e.g., DR3 direction) perpendicular to a first direction (e.g., DR1 direction) and a second direction (e.g., DR2 direction). The image IM may include not only moving images but also still images.

The electronic device 1000 may detect an external input such as a user input TC received from the outside. The user input TC may include various types of external inputs applied using a portion of the user's body, light, heat, pressure, or the like. In an embodiment, the user input TC is illustrated touch input as being applied by the user's hand on the front of the electronic device 1000. However, the disclosure is not limited thereto. The user input TC may be provided in various ways. The electronic device 1000 may detect the user input TC applied to a side or back of the electronic device 1000 depending on a structure of the electronic device 1000.

The electronic device 1000 may include a cover window CW, a housing HU, and a display panel 1. In an embodiment, the cover window CW may be combined with the housing HU to form the exterior of the electronic device 1000.

The cover window CW may include a light-transmitting area LTA and a bezel area BZA. The light-transmitting area LTA may be an optically transparent area. In an embodiment, the light-transmitting area LTA may be an area with visible light transmittance of greater than about 90%, for example.

The bezel area BZA may define the shape of the light-transmitting area LTA. The bezel area BZA may be next (or adjacent) to the light-transmitting area LTA and may surround the light-transmitting area LTA. The bezel area BZA may be an area with relatively low light transmittance compared to the light-transmitting area LTA. The bezel area BZA may include an opaque material that blocks light. The bezel area BZA may have a predetermined color. The bezel area BZA may be defined by a bezel layer provided separately from the transparent substrate defining the light-transmitting area LTA, or may be defined by an ink layer formed by inserting or coloring the transparent substrate.

The housing HU may be combined with the cover window CW. The housing HU may accommodate the display panel 1. The housing HU may include a rear surface and a side surface. The cover window CW may be disposed on a front of the housing HU. In other words, the cover window CW may be disposed above the housing HU. The housing HU may be combined with the cover window CW to provide an accommodation space. The display panel 1 may be accommodated in the accommodation space provided between the housing HU and the cover window CW.

The housing HU may include a material having relatively high rigidity. In an embodiment, the housing HU may include glass, plastic, or metal, or include a plurality of frames and/or plates including any combinations thereof, for example. The housing HU may reliably protect the elements of the electronic device 1000 housed in the accommodation space from external impact.

The display panel 1 may display the image IM. The display panel 1 may include a display area DA and a non-display area NDA. The display area DA may be an active area that is activated by an electrical signal.

In an embodiment, the display area DA may be an area where the image IM is displayed and at the same time an area where the user input TC is detected. The display area DA may be an area where a plurality of subpixels P are arranged.

The display area DA may at least partially overlap the light-transmitting area LTA of the cover window CW. In an embodiment, the display area DA and the light-transmitting area LTA may overlap partially or entirely, for example. Accordingly, the user may recognize the image IM or provide the user input TC through the light-transmitting area LTA. However, the disclosure is not limited thereto. In an embodiment, an area where the image IM is displayed and an area where the user input TC is detected within the display area DA may be separate from each other, for example.

The non-display area NDA may at least partially overlap the bezel area BZA of the cover window CW. The non-display area NDA may be an area covered by the bezel area BZA. The non-display area NDA may be next (or adjacent) to the display area DA. The non-display area NDA may surround the display area DA. The non-display area NDA may be an area where the image IM is not displayed. A driving circuit or driving wiring for driving the display area DA may be disposed in the non-display area NDA.

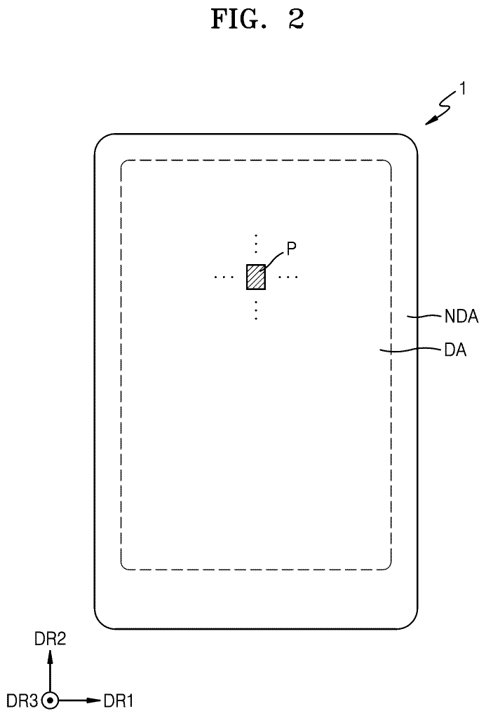

FIG. 2 is a schematic plan view of an embodiment of the display panel 1.

Referring to FIG. 2, the display panel 1 may include the display area DA and the non-display area NDA disposed outside the display area DA.

The display area DA may display an image IM (refer to FIG. 1) through subpixels P arranged in the display area DA. Each subpixel P may include a display element, such as a light-emitting element. Each subpixel P may emit light of, e.g., red, green, blue or white.

The non-display area NDA may be disposed outside the display area DA and may not display an image IM (refer to FIG. 1), and may surround the display area DA. A driver or the like that provides electrical signals or power to the display area DA may be disposed in the non-display area NDA. A pad may be disposed in the non-display area NDA. The pad may be electrically connected to electronic components or printed circuit boards.

As shown in FIG. 2, in an embodiment, the display area DA may be a polygon (e.g., a rectangle) where a length in the first direction (e.g., the DR1 direction) is smaller than a length in the second direction (e.g., the DR2 direction). However, the disclosure is not limited thereto. In another embodiment, the display area DA may be a polygon (e.g., a rectangle) where the length in the second direction (e.g., the DR2 direction) is smaller than the length in the first direction (e.g., the DR1 direction). FIG. 2 illustrates that the display area DA is approximately square, but the disclosure is not limited thereto. In an embodiment, the display area DA may have various shapes, such as an N-gon (N is a natural number greater than or equal to 3), a circle, or an ellipse. As illustrated in FIG. 2, the display area DA may be a polygon with rounded corners, but in another embodiment, corners of the display area DA may have a shape including vertices where straight lines intersect.

The display panel 1 may include the light-emitting element as the display element, and the light-emitting element may be an organic light-emitting element including an organic emission layer. In an alternative embodiment, the light-emitting element may be an inorganic light-emitting element including an inorganic emission layer. The size of the light-emitting element may be micro-scale or nano-scale. In an embodiment, the light-emitting element may be a micro light-emitting element, for example. In an alternative embodiment, the light-emitting element may be a nanorod light-emitting element. The nanorod light-emitting element may include gallium nitride (GaN). In an embodiment, a color conversion layer may be disposed on the nanorod light-emitting element. The color conversion layer may include quantum dots. In an alternative embodiment, the light-emitting element may be a quantum dot light-emitting diode including a quantum dot emission layer.

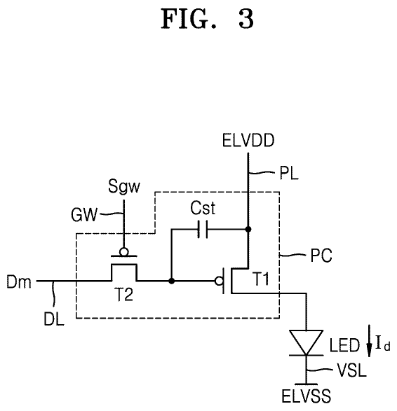

FIG. 3 is a schematic equivalent circuit diagram of an embodiment of the light-emitting element LED corresponding to the subpixel P (refer to FIG. 2) of the display panel 1 (refer to FIG. 2) and a subpixel circuit PC electrically connected to the light-emitting element LED.

Referring to FIG. 3, the light-emitting element LED is electrically connected to the subpixel circuit PC, and the subpixel circuit PC may include a first transistor T1, a second transistor T2, and a storage capacitor Cst. A pixel electrode (e.g., an anode) of the light-emitting element LED may be electrically connected to the first transistor T1. A counter electrode (e.g., a cathode) may be electrically connected to an auxiliary wire VSL, and may receive a voltage corresponding to a common voltage ELVSS through the auxiliary wire VSL.

The second transistor T2 may transfer a data signal Dm input through a data line DL to the first transistor T1 according to a scan signal Sgw input through a scan line GW.

The storage capacitor Cst may be connected to the second transistor T2 and a driving voltage line PL, and store a voltage corresponding to the difference between a voltage received from the second transistor T2 and a driving voltage ELVDD supplied to the driving voltage line PL.

The first transistor T1 may be connected to the driving voltage line PL and the storage capacitor Cst, and may control a driving current Id flowing from the driving voltage line PL to the light-emitting element LED in response to a voltage value stored in the storage capacitor Cst. The light-emitting element LED may emit light with a predetermined brightness depending on a driving current Id.

Although FIG. 3 illustrates that the subpixel circuit PC includes two transistors and one storage capacitor, it is to be understood that in other embodiments, the number of transistors or the number of storage capacitors may vary depending on the design of the subpixel circuit PC.

In an embodiment, each of the first transistor T1 and the second transistor T2 may be provided as a p-channel metal-oxide-semiconductor (“PMOS”) or an n-channel metal-oxide-semiconductor (“NMOS”). In an alternative embodiment, some of the plurality of transistors included in the subpixel circuit PC may be PMOS, and remaining (or the other) ones may be NMOS.

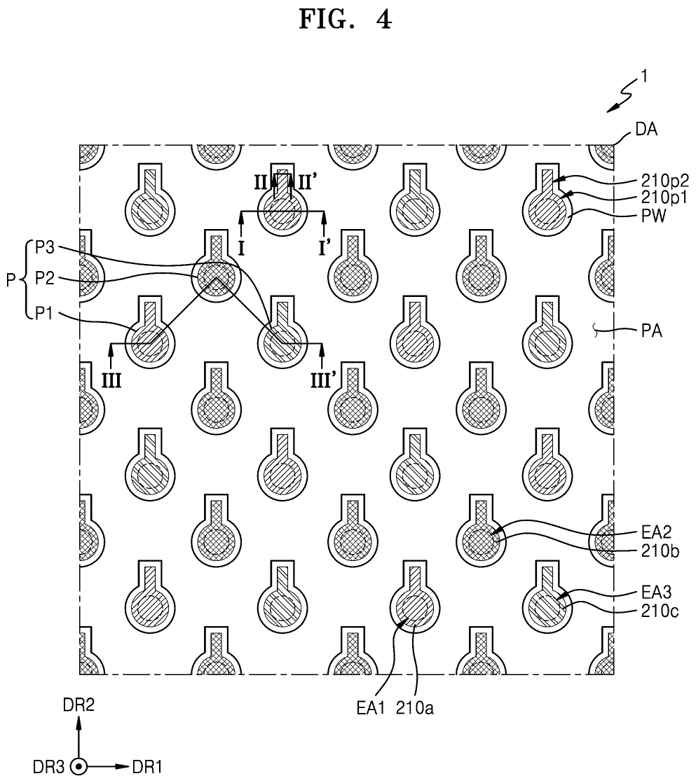

FIG. 4 is an enlarged plan view of an embodiment of a portion of the display area DA of the display panel 1. FIG. 4 illustrates the arrangement of pixel electrodes and light-emitting areas of the plurality of subpixels P, and conductive partition walls PW.

Referring to FIG. 4, the display panel 1 may include the plurality of subpixels P in the display area DA, and the plurality of subpixels P may include a first subpixel P1, a second subpixel P2, and a third subpixel P3 that emit light of different colors. In an embodiment, the first subpixel P1 may emit red light, the second subpixel P2 may emit green light, and the third subpixel P3 may emit blue light, for example. However, it is not limited thereto. In an embodiment, various variations are possible, such as the first subpixel P1 emitting blue light, the second subpixel P2 emitting green light, and the third subpixel P3 emitting red light, for example.

As shown in FIG. 4, the first subpixel P1, the second subpixel P2, and the third subpixel P3 may be arranged in a pixel array of a PENTILE® structure, but this is merely one of embodiments and is not limited thereto. In an embodiment, the first subpixel P1, the second subpixel P2, and the third subpixel P3 may be arranged in various pixel arrangement structures such as a stripe structure, a mosaic structure, and a delta structure, for example.

In FIG. 4, the sizes (or areas) of the first subpixel P1, the second subpixel P2, and the third subpixel P3 are depicted as being substantially the same, but this is merely one of embodiments and is not limited thereto. In an embodiment, the sizes (or areas) of the first subpixel P1, the second subpixel P2, and the third subpixel P3 may be different from each other. In an embodiment, the size (or area) of the second subpixel P2 may be smaller than the size (or area) of the first subpixel P1 and the third subpixel P3, and the size (or area) of the third subpixel P3 may be larger than the size (or area) of the first subpixel P1, for example.

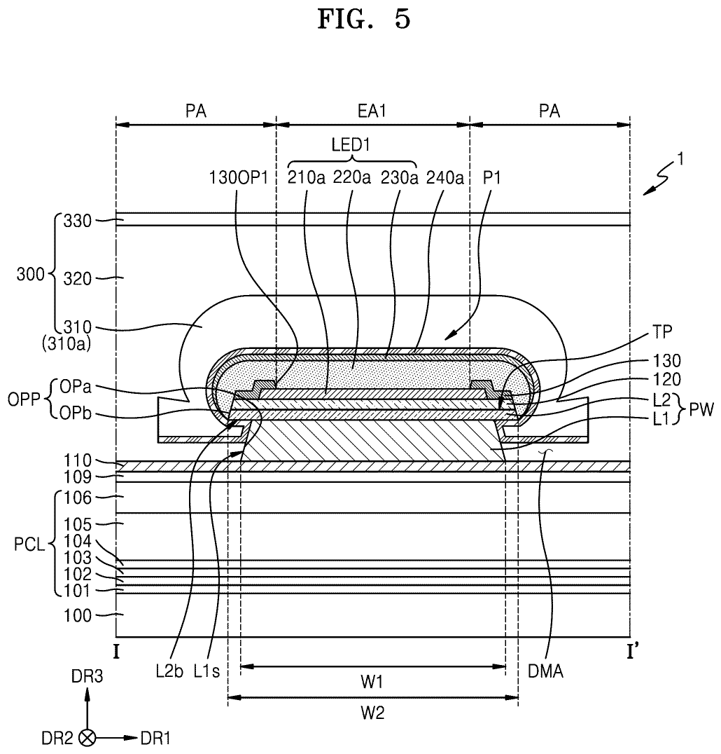

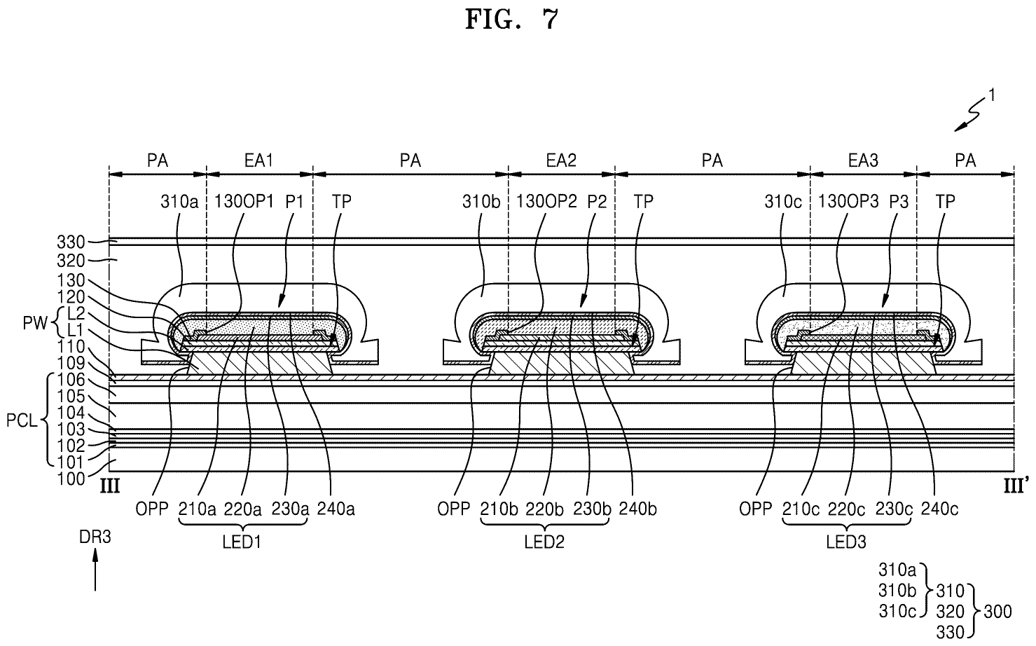

In this specification, the size (or area) of each of the plurality of subpixels P may refer to the size (or area) of the light-emitting area of light-emitting element that constitutes each subpixel P, in a plan view. The light-emitting area may be defined by a pixel opening of a pixel defining layer 130 (refer to FIG. 5) described below. In an embodiment, the sizes (or areas) of the first subpixel P1, the second subpixel P2, and the third subpixel P3 refer to the sizes (or areas) of a first light-emitting area EA1, a second light-emitting area EA2, and a third light-emitting area EA3, respectively. The first light-emitting area EA1, the second light-emitting area EA2, and the third light-emitting area EA3 may be defined by a first pixel opening 130OP1 (refer to FIG. 7), a second pixel opening 130OP2 (refer to FIG. 7), and a third pixel opening 130OP3 (refer to FIG. 7) of the pixel defining layer 130, respectively, for example.

In FIG. 4, the first light-emitting area EA1, the second light-emitting area EA2, and the third light-emitting area EA3 are illustrated as being circular, but this is only an illustrative embodiment and is not limited thereto. In an embodiment, the first light-emitting area EA1, the second light-emitting area EA2, and the third light-emitting area EA3 may be polygonal, polygonal with rounded corners, circle or oval in a plan view.

The display area DA may include the first light-emitting area EA1, the second light-emitting area EA2, and the third light-emitting area EA3, which correspond to the first subpixel P1, the second subpixel P2, and the third subpixel P3, respectively, and a peripheral area PA disposed outside the first to third light-emitting areas EA1, EA2, and EA3. The peripheral area PA may surround each of the first to third light-emitting areas EA1, EA2, and EA3.

The display panel 1 may include a plurality of conductive partition walls PW spaced apart from each other in a plan view. In a plan view, each of the conductive partition walls PW may have an island-shaped pattern. Each of the conductive partition walls PW may overlap with the light-emitting element of the subpixel P in a plan view. In an embodiment, one of the conductive partition walls PW may overlap with a first light-emitting element of the first subpixel P1 (e.g., a first pixel electrode 210a of the first light-emitting element), another one of the conductive partition walls PW may overlap with second light-emitting element of a second subpixel P2 (e.g., a second pixel electrode 210b of the second light-emitting element), and yet another one of the conductive partition walls PW may overlap with a third light-emitting element of a third subpixel P3 (e.g., a third pixel electrode 210c of the third light-emitting element), for example.

In an embodiment, each of the first to third pixel electrodes 210a, 210b, and 210c may include a first portion 210p1 overlapping the light-emitting area and a second portion 210p2 extending from one side of the first portion 210p1. The second portion 210p2 may protrude from the first portion 210p1. In an embodiment, the first portion 210p1 of the first pixel electrode 210a may overlap with the first light-emitting area EA1, the first portion 210p1 of the second pixel electrode 210b may overlap with the second light-emitting area EA2, and the first portion 210p1 of the third pixel electrode 210c may overlap with the third light-emitting area EA3, for example. In an embodiment, the second portion 210p2 of each of the first to third pixel electrodes 210a, 210b, and 210c may not overlap with the first to third light-emitting areas EA1, EA2, and EA3, respectively, for example.

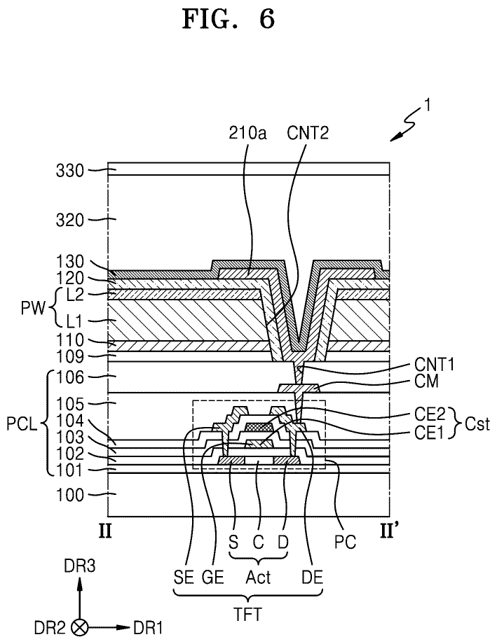

FIG. 5 is a schematic cross-sectional view of a section of the display panel 1, taken along line I-I′ of FIG. 4. FIG. 6 is a schematic cross-sectional view of a section of the display panel 1, taken along line II-II′ of FIG. 4. FIG. 5 illustrates an embodiment of a structure in a cross-section of the first subpixel P1. Because the structure of the first subpixel P1, in the cross-sectional view, is substantially the same as or similar to the structures of each of the second subpixel P2 and the third subpixel P3, the description of the structure of the first subpixel P1 described with reference to FIG. 5 may also be applied to the structures of each of the second subpixel P2 and the third subpixel P3.

Referring to FIGS. 5 and 6, the display panel 1 may include a substrate 100, a pixel circuit layer PCL, an upper insulating layer 109, a common electrode 110, a conductive partition wall PW, a partition wall insulation layer 120, a pixel defining layer 130, a first light-emitting element LED1, a first auxiliary electrode 240a, and an encapsulation layer 300.

The substrate 100 may include glass or polymer resin. In an embodiment, the polymer resin may include polyethersulfone, polyacrylate, polyether imide, polyethylene naphthalate, polyethylene terephthalate, polyphenylene sulfide, polyarylate, polyimide, polycarbonate, cellulose acetate propionate, or combinations thereof, for example. The substrate 100 including the polymer resin may have flexible, rollable or bendable properties. The substrate 100 may have a multi-layer structure including a layer including the polymer resin and an inorganic layer.

The pixel circuit layer PCL may be disposed on the substrate 100. The pixel circuit layer PCL may include a subpixel circuit PC and insulating layers. The subpixel circuit PC may include the transistor and the storage capacitor Cst as described with reference to FIG. 3. In an embodiment, FIG. 6 illustrates a thin film transistor TFT and the storage capacitor Cst provided in the subpixel circuit PC, for example.

The pixel circuit layer PCL may include a buffer layer 101, a first gate insulating layer 102, a second gate insulating layer 103, an inter-insulating layer 104, a thin film transistor TFT, a first via insulating layer 105, and a second via insulating layer 106.

The buffer layer 101 may be disposed on the substrate 100 and may reduce or block the penetration of foreign substances, moisture or external air from under the substrate 100 and provide a flat surface on the substrate 100. The buffer layer 101 may include an inorganic material such as an oxide or a nitride, an organic material, or an organic-inorganic composite. The buffer layer 101 may include a single-layer or multi-layer structure comprising an inorganic material and an organic material. The display panel 1 may further include a barrier layer (not shown) that blocks penetration of external air. The barrier layer may be disposed between the substrate 100 and the buffer layer 101. The buffer layer 101 may include silicon oxide (SiO₂) or silicon nitride (SiNₓ).

The thin film transistor TFT may be disposed in plural on the buffer layer 101. Each of the plurality of thin film transistors TFT may include a semiconductor layer Act, a gate electrode GE, a source electrode SE, and a drain electrode DE. The plurality of thin film transistors TFT may be electrically connected to the light-emitting element LED (refer to FIG. 3) and drive the light-emitting element LED.

The semiconductor layer Act may be disposed on the buffer layer 101. The semiconductor layer Act may include an oxide semiconductor and/or a silicon semiconductor. The semiconductor layer Act may include a channel region C overlapping with a gate electrode GE, a source region S and a drain region D doped with impurities and disposed on opposite sides of the channel region C. When the semiconductor layer Act includes an oxide semiconductor, the semiconductor layer Act may include an oxide of at least one or more material selected from the group including or consisting of, e.g., indium (In), gallium (Ga), tin (Sn), zirconium (Zr), vanadium (V), hafnium (Hf), cadmium (Cd), germanium (Ge), chromium (Cr), titanium (Ti), and zinc (Zn). In an embodiment, the semiconductor layer Act may be an InSnZnO (“ITZO”) semiconductor layer, an InGaZnO (“IGZO”) semiconductor layer, or the like, for example. When the semiconductor layer Act includes a silicon semiconductor, the semiconductor layer Act may include amorphous silicon or low temperature poly-silicon (“LTPS”), for example.

The first gate insulating layer 102 may be disposed on the buffer layer 101. The first gate insulating layer 102 may be disposed between the semiconductor layer Act and the gate electrode GE. The first gate insulating layer 102 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO or ZnO₂).

The gate electrode GE may be disposed on the semiconductor layer Act. The gate electrode GE may be disposed on the first gate insulating layer 102. The gate electrode GE may overlap with the channel region C of the semiconductor layer Act. The gate electrode GE may include a low-resistance metal material. In an embodiment, the gate electrode GE may include metal such as aluminum (Al), platinum (Pt), palladium (Pd), silver (Ag), magnesium (Mg), gold (Au), nickel (Ni), neodymium (Nd), iridium (Ir), chromium (Cr), nickel (Li), calcium (Ca), molybdenum (Mo), titanium (Ti), tungsten (W), or copper (Cu), for example. The gate electrode GE may include single layer or multi-layer including the above-described metal. The gate electrode GE may be connected to a gate line that applies an electrical signal to the gate electrode GE.

The second gate insulating layer 103 may be disposed on the first gate insulating layer 102. The second gate insulating layer 103 may cover the gate electrode GE. The second gate insulating layer 103 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO or ZnO₂).

A second capacitor electrode CE2 of a storage capacitor Cst may be disposed on the second gate insulating layer 103. In an embodiment, the second capacitor electrode CE2 may overlap with the gate electrode GE. In this case, the overlapping gate electrode GE and the second capacitor electrode CE2 may form a storage capacitor Cst. In other words, the gate electrode GE may function as a first capacitor electrode CE1 of the storage capacitor Cst. In an embodiment, the storage capacitor Cst and the thin film transistor TFT may overlap each other. In another embodiment, the storage capacitor Cst and the thin film transistor TFT may not overlap each other.

The inter-insulating layer 104 may be disposed on the second gate insulating layer 103. The inter-insulating layer 104 may cover the second capacitor electrode CE2. The inter-insulating layer 104 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO or ZnO₂). The inter-insulating layer 104 may be a single layer or multi-layer including the above-described inorganic insulating material.

The source electrode SE and the drain electrode DE may each be disposed on the inter-insulating layer 104. The source electrode SE and the drain electrode DE may be electrically connected to the semiconductor layer Act through contact holes defined in the first gate insulating layer 102, the second gate insulating layer 103, and the inter-insulating layer 104. The source electrode SE and drain electrode DE may each include a material with good conductivity. At least one of the source electrode SE and the drain electrode DE may include a conductive material including molybdenum (Mo), aluminum (Al), copper (Cu), or titanium (Ti). Each of the source electrode SE and the drain electrode DE may include a multi-layer or single layer including the above-described conductive material. In an embodiment, at least one of the source electrode SE and the drain electrode DE may have a multi-layer structure of Ti/Al/Ti.

The first via insulating layer 105 and the second via insulating layer 106 may be disposed on the source electrode SE and the drain electrode DE. The first via insulating layer 105 and the second via insulating layer 106 may planarize an upper surface of the subpixel circuit PC including the thin film transistor TFT, thereby planarizing a surface where the first light-emitting element LED1 will be disposed. The first via insulating layer 105 and the second via insulating layer 106 may be also referred to as a first planarization insulating layer and a second planarization insulating layer, respectively. In FIGS. 5 and 6, the display panel 1 is illustrated as including two via insulating layers, but is not limited thereto, and the display panel 1 may include a single-layer via insulating layer or two or more multi-layer via insulating layers.

The first via insulating layer 105 is disposed on the inter-insulating layer 104 and may be disposed on the source electrode SE and the drain electrode DE. A connection electrode CM may be disposed on the first via insulating layer 105. The connection electrode CM is disposed between the thin film transistor TFT and the first light-emitting element LED1, and may electrically connect the thin film transistor TFT and the first light-emitting element LED1. The second via insulating layer 106 may be disposed on the first via insulating layer 105. The second via insulating layer 106 may be disposed on the connection electrode CM.

Each of the first via insulating layer 105 and the second via insulating layer 106 may be an organic insulating layer including an organic material. Each of the first via insulating layer 105 and the second via insulating layer 106 may include an organic material such as a general-purpose polymer, including photosensitive polyimide (“PSPI”), polyimide, polystyrene (“PS”), polycarbonate (“PC”), benzocyclobutene (“BCB”), hexamethyldisiloxane (“HMDSO”), or polymethylmethacrylate (“PMMA”), a polymer derivative including or consisting of a phenol group, an acrylic polymer, an imide polymer, an aryl ether polymer, an amide polymer, a fluorinated polymer, a p-xylene polymer, a vinyl alcohol polymer, or any combinations thereof.

The upper insulating layer 109 may be disposed on the pixel circuit layer PCL. In an embodiment, the upper insulating layer 109 may be disposed on the second via insulating layer 106 and cover the second via insulating layer 106. Referring to FIG. 6, the upper insulating layer 109 may define a portion of a second contact hole CNT2 described below. The second contact hole CNT2 may be defined through which the first pixel electrode 210a is connected to the connection electrode CM. The upper insulating layer 109 may be an organic insulating layer or an inorganic insulating layer.

The common electrode 110 may be disposed on the upper insulating layer 109. In an embodiment, the common electrode 110 may be disposed on the thin film transistor TFT of a pixel circuit layer PCL, for example. The common electrode 110 may be disposed over the entirety of the surface of the display area DA (refer to FIG. 2). In an embodiment, the common electrode 110 may overlap each of the first to third light-emitting areas EA1, EA2, and EA3 (refer to FIG. 4), for example. The common electrode 110 may transmit the common voltage ELVSS (refer to FIG. 3). Referring to FIG. 6, the common electrode 110 may define a portion of the second contact hole CNT2.

The common electrode 110 may include a conductive material. In an embodiment, the common electrode 110 may include gold (Au), silver (Ag), aluminum (Al), magnesium (Mg), lithium (Li), molybdenum (Mo), titanium (Ti), copper (Cu), or an alloy, for example. In an embodiment, the common electrode 110 may include a transparent conductive oxide such as indium tin oxide (“ITO”), indium zinc oxide (“IZO”), zinc oxide, indium oxide, indium gallium oxide, indium gallium zinc oxide (“IGZO”), or aluminum zinc oxide, for example.

The conductive partition wall PW may be disposed on the common electrode 110. The conductive partition wall PW may be electrically connected to the common electrode 110. The conductive partition wall PW may be disposed between the pixel circuit layer PCL and the first light-emitting element LED1 in the cross-sectional view. The conductive partition wall PW may overlap with the first light-emitting element LED1 in a direction perpendicular to the upper surface of the substrate 100 (e.g., in the DR3 direction). In an embodiment, the conductive partition wall PW may overlap with the first pixel electrode 210a of the first light-emitting element LED1, for example. In an embodiment, the conductive partition wall PW may overlap with the first light-emitting area EA1, for example. In other words, the conductive partition wall PW may overlap with the first pixel opening 130OP1 of the pixel defining layer 130.

The conductive partition wall PW may have an undercut shape (or undercut structure) in the cross-sectional view. The conductive partition wall PW may include a plurality of sequentially stacked layers, and have the undercut shape (or undercut structure) in which at least one of the plurality of layers is recessed relative to remaining (or the other) layers.

In an embodiment, the conductive partition wall PW may include a first partition wall layer L1 and a second partition wall layer L2. The first partition wall layer L1 may be disposed on the common electrode 110, and the second partition wall layer L2 may be disposed on the first partition wall layer L1. In an embodiment, the first partition wall layer L1 may be electrically connected to the common electrode 110. In an embodiment, the first partition wall layer L1 may contact the common electrode 110. In an embodiment, the second partition wall layer L2 may be electrically connected to the first partition wall layer L1. In an embodiment, the second partition wall layer L2 may contact the first partition wall layer L1.

In an embodiment, as illustrated in FIGS. 5 and 6, a thickness of the first partition wall layer L1 may be greater than a thickness of the second partition wall layer L2. In an embodiment, the thickness of the first partition wall layer L1 may be equal to or less than the thickness of the second partition wall layer L2.

In the cross-sectional view, the first partition wall layer L1 and the second partition wall layer L2 overlap each other, and a width W2 of the second partition wall layer L2 in the first direction (e.g., the DR1 direction) is larger than a width W1 of the first partition wall layer L1 in the first direction (e.g., the DR1 direction), so that the conductive partition wall PW may have a tip portion TP. A side surface of the second partition wall layer L2 may protrude in an outward direction of the conductive partition wall PW (e.g., in a direction opposite to a direction toward a center of the conductive partition wall PW) more than a side surface of the first partition wall layer L1. In other words, the side surface of the first partition wall layer L1 may be recessed inwardly (e.g., toward the center of the conductive partition wall PW) more than the side surface of the second partition wall layer L2. A portion of the second partition wall layer L2 protruding in the outward direction of the conductive partition wall PW more than the first partition wall layer L1 may correspond to the tip portion TP of the conductive partition wall PW.

Referring to FIGS. 4 and 5 together, the plurality of conductive partition walls PW may define a partition wall opening OPP. In an embodiment, the partition wall opening OPP may be defined as a space between the plurality of conductive partition walls PW, for example. The partition wall opening OPP may include a first partition wall opening OPa defined by first partition wall layers L1 of the plurality of conductive partition walls PW and a second partition wall opening OPb defined by second partition wall layers L2 of the plurality of conductive partition walls PW. A width of the first partition wall opening OPa in the first direction (e.g., in the DR1 direction) may be greater than a width of the second partition wall opening OPb in the first direction (e.g., in the DR1 direction).

Each of the first partition wall layer L1 and the second partition wall layer L2 may include a conductive material.

In an embodiment, the first partition wall layer L1 may include an aluminum alloy. In an embodiment, the first partition wall layer L1 may include the aluminum alloy that includes aluminum (Al) as a main component and further includes at least one impurity metal selected from nickel (Ni), lanthanum (La), neodymium (Nd), or germanium (Ge), for example. In a case that the first partition wall layer L1 includes one impurity metal selected from nickel (Ni), lanthanum (La), neodymium (Nd), or germanium (Ge), an atomic ratio of the one impurity metal may be in a range of about 0.06 at % to about 1 at % based on total atoms in the aluminum alloy, and in a case that two or more impurity metals are selected from nickel (Ni), lanthanum (La), neodymium (Nd), or germanium (Ge), a sum of respective atomic ratios of the two or more impurity metals selected from nickel (Ni), lanthanum (La), neodymium (Nd), or germanium (Ge) included in the aluminum alloy may be in a range of about 0.06 at % to about 1 at % based on total atoms in the aluminum alloy. In an embodiment, the first partition wall layer L1 may include an aluminum-nickel-lanthanum alloy (Al—Ni—La alloy), for example. In this case, in the aluminum-nickel-lanthanum alloy (Al—Ni—La alloy), a sum of an atomic ratio of nickel (Ni) and an atomic ratio of lanthanum (La) may be in a range of about 0.06 at % to about 1 at % based on total atoms in the aluminum alloy. In a case of the sum of respective atomic ratios of the impurity metals included in the aluminum alloy is 0.06 at % or more, the conductive partition walls PW may have relatively high thermal resistance and occurrence of hillock defects in the conductive partition wall PW may be reduced or prevented. In other words, in a case of the sum of respective atomic ratios of the impurity metals included in the aluminum alloy is less than 0.06 at %, occurrence of hillock defects in the conductive partition wall PW may increase when heat is applied. When the sum of atoms of impurity metals included in the aluminum alloy exceeds 1 at %, an etching process for forming a conductive partition wall PW may not be performed easily.

Because aluminum alloy has higher thermal resistance than pure aluminum that does not include or consist of impurity metal, when the first partition wall layer L1 includes the aluminum alloy in an embodiment, the occurrence of hillock defects in the conductive partition wall PW may be prevented or reduced compared to a comparative example in which the first partition wall layer L1 includes pure aluminum. When a hillock defect occurs in the first partition wall layer L1 of the conductive partition wall PW, a crack or seam may occur in the first pixel electrode 210a of the first light-emitting element LED1 disposed on the conductive partition wall PW, and the first pixel electrode 210a may be damaged. In an embodiment, the display panel 1 may improve the reliability of the display panel 1 by preventing or reducing hillock defects and preventing or reducing defects in light-emitting elements, as the first partition wall layer L1 of the conductive partition wall PW includes the aluminum alloy rather than pure aluminum.

In an embodiment, the second partition wall layer L2 may include a different conductive material from that of the first partition wall layer L1. In an embodiment, the second partition wall layer L2 may include gold (Au), magnesium (Mg), lithium (Li), molybdenum (Mo), titanium (Ti), copper (Cu), or an alloy, for example. In an embodiment, the second partition wall layer L2 may include a transparent conductive oxide such as ITO, IZO, zinc oxide, indium oxide, indium gallium oxide, IGZO, or aluminum zinc oxide, for example. In an embodiment, the first partition wall layer L1 may include the aluminum alloy, and the second partition wall layer L2 may include titanium (Ti). In an embodiment, the second partition wall layer L2 may include the same material as that of the common electrode 110, for example, but is not limited thereto.

In FIG. 5, a tapered shape in which a side surface of the conductive partition wall PW is inclined with respect to an upper surface of the common electrode 110 is illustrated in an embodiment, but is not limited thereto. In an embodiment, the side surface of the conductive partition wall PW may be perpendicular to the upper surface of the common electrode 110 or may be inclined to have a reverse taper shape, for example.

The partition wall insulation layer 120 may be disposed on the conductive partition wall PW. The partition wall insulation layer 120 may be disposed between the conductive partition wall PW and the first light-emitting element LED1. The partition wall insulation layer 120 may be disposed between the conductive partition wall PW and the first pixel electrode 210a of the first light-emitting element LED1, thereby preventing the conductive partition wall PW and the first pixel electrode 210a from being electrically connected. Referring to FIG. 6, the partition wall insulation layer 120 may cover side surfaces of the conductive partition wall PW, the common electrode 110, and the upper insulating layer 109 defining the second contact hole CNT2.

The first light-emitting element LED1 may include a first pixel electrode 210a, a first intermediate layer 220a, and a first counter electrode 230a. The first light-emitting element LED1 may be disposed on the conductive partition wall PW. In an embodiment, a distance from the substrate 100 to the first pixel electrode 210a of the first light-emitting element LED1 may be greater than a distance from the substrate 100 to the second partition wall layer L2, for example.

The first pixel electrode 210a may be disposed on the partition wall insulation layer 120. The first pixel electrode 210a may be disposed between the common electrode 110 and the first counter electrode 230a, in the cross-sectional view. In an embodiment, as illustrated in FIG. 6, the first pixel electrode 210a may be electrically connected to the connection electrode CM through a first contact hole CNT1 defined in the second via insulating layer 106. The first pixel electrode 210a may be electrically connected to the thin film transistor TFT through the connection electrode CM.

In an embodiment, a portion of the first pixel electrode 210a illustrated in FIG. 5 may correspond to the first portion 210p1 of the first pixel electrode 210a described with reference to FIG. 4, and a portion of the first pixel electrode 210a illustrated in FIG. 6 may correspond to the second portion 210p2 of the first pixel electrode 210a described with reference to FIG. 4. The first pixel electrode 210a is electrically insulated from the conductive partition wall PW by the partition wall insulation layer 120 and may be electrically connected to the thin film transistor TFT of the subpixel circuit PC.

The first pixel electrode 210a may include a metal and/or a conductive oxide. The first pixel electrode 210a may be a reflective electrode. In an embodiment, the first pixel electrode 210a may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. The first pixel electrode 210a may have a transparent or semitransparent conductive layer below and/or above the aforementioned reflective layer, for example. The transparent or semitransparent conductive layer may include at least one material selected from the group including or consisting of ITO, IZO, zinc oxide (ZnO), indium oxide (In₂O₃), indium gallium oxide (“IGO”), and aluminum zinc oxide (“AZO”). In an embodiment, the first pixel electrode 210a may have a stacked structure of ITO/Ag/ITO, for example.

The pixel defining layer 130 may be disposed on the partition wall insulation layer 120. The pixel defining layer 130 is disposed on the first pixel electrode 210a and may include a first pixel opening 130OP1 that exposes at least a portion of the first pixel electrode 210a. In other words, at least a portion of an upper surface of the first pixel electrode 210a may be exposed by the first pixel opening 130OP1 defined in the pixel defining layer 130. The first light-emitting area EA1 of the first subpixel P1 may be defined by the first pixel opening 130OP1 that exposes at least a portion of the first pixel electrode 210a. The pixel defining layer 130 may include an organic insulating material such as polyimide, polyamide, acrylic resin, benzocyclobutene, hexamethyldisiloxane (“HMDSO”), or phenol resin, or an inorganic insulating material such as silicon nitride or silicon oxide.

The first intermediate layer 220a may be disposed on the first pixel electrode 210a. The first intermediate layer 220a may include a first emission layer including a light-emitting material. The first intermediate layer 220a may include a first common layer disposed between the first pixel electrode 210a and the first emission layer and/or a second common layer disposed between the first emission layer and the first counter electrode 230a. In an embodiment, the first emission layer may include a polymer or relatively small molecule organic material that emits light of a predetermined color (red, green, or blue). In another embodiment, the first emission layer may include an inorganic material or quantum dots. The first common layer may include a hole transport layer (“HTL”) and/or a hole injection layer (“HIL”). The second common layer may include an electron transport layer (“ETL”) and/or an electron injection layer (“EIL”).

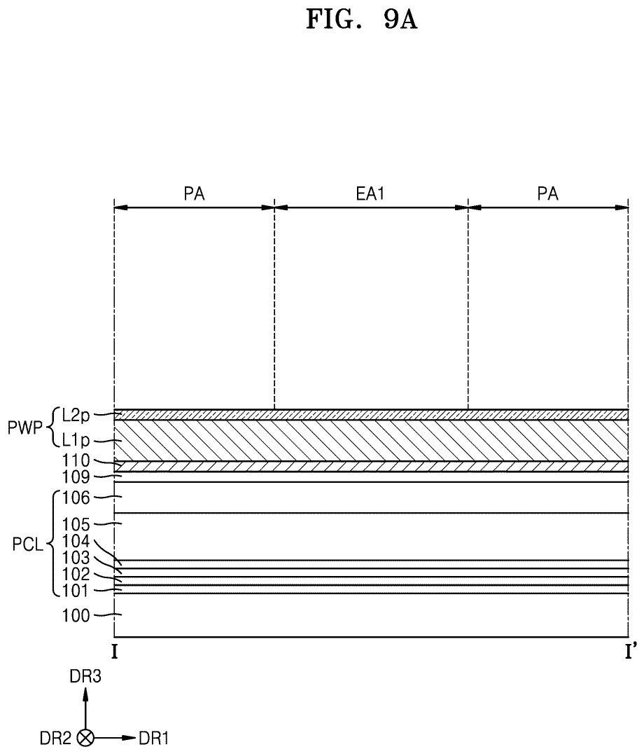

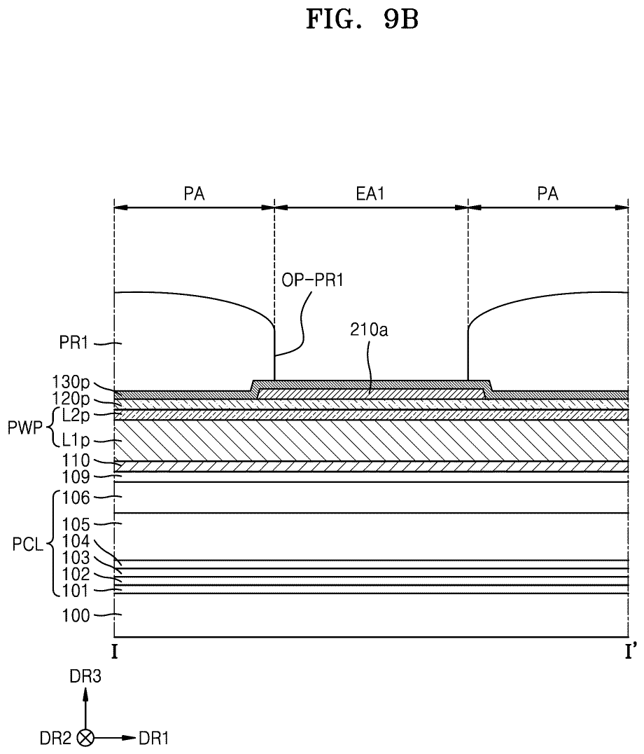

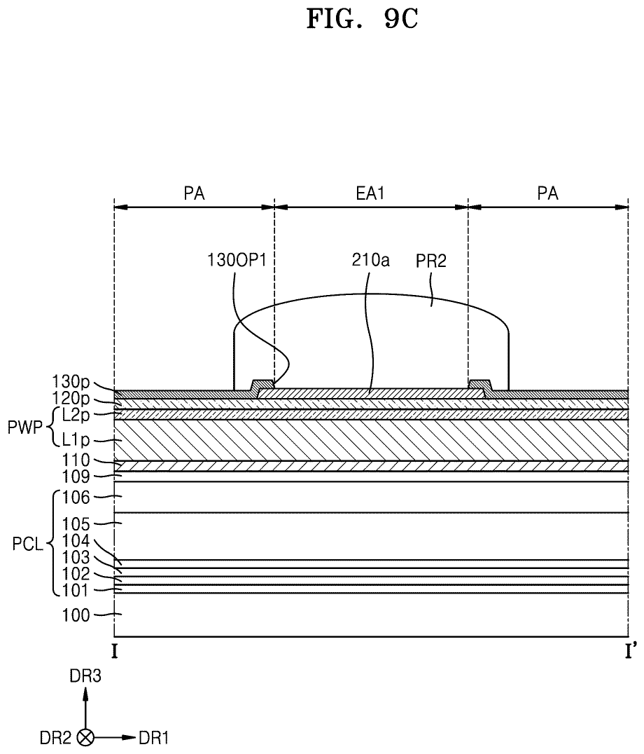

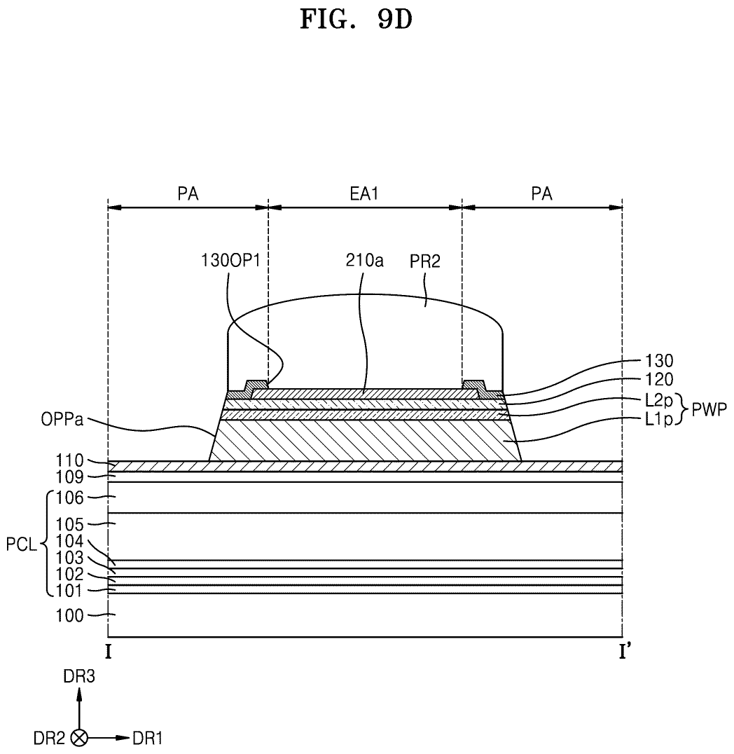

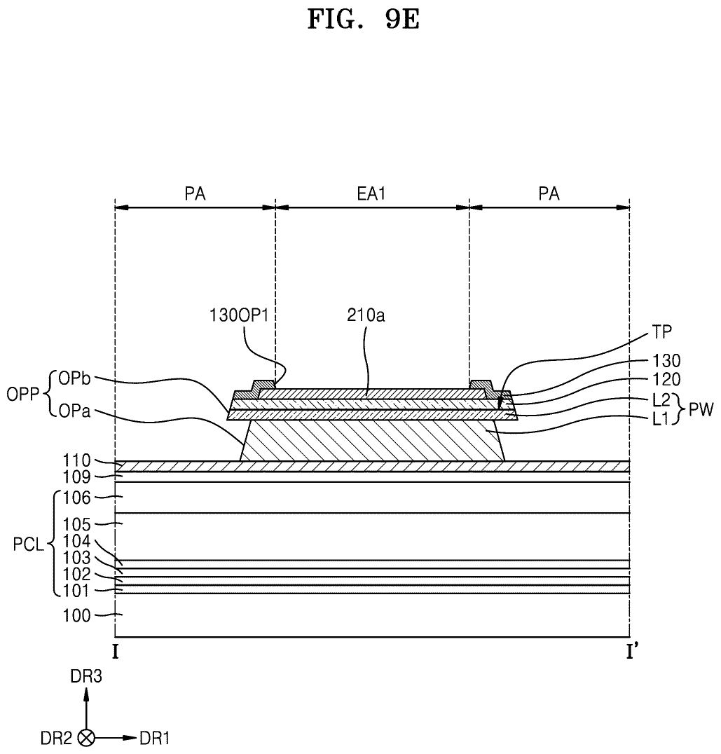

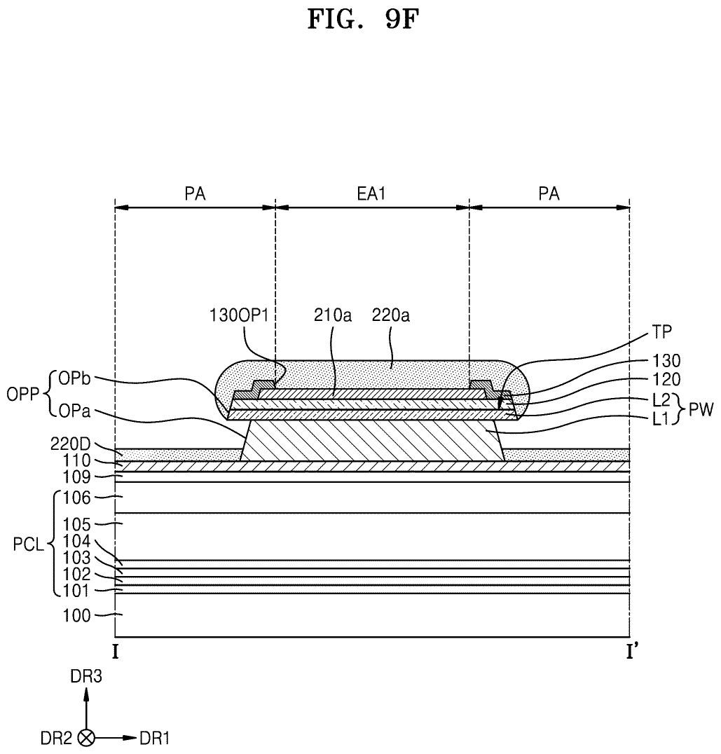

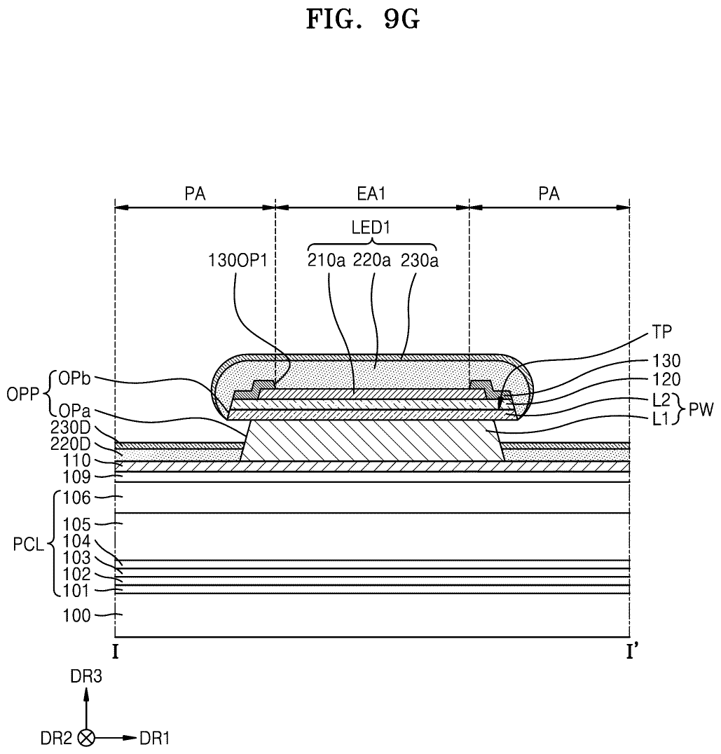

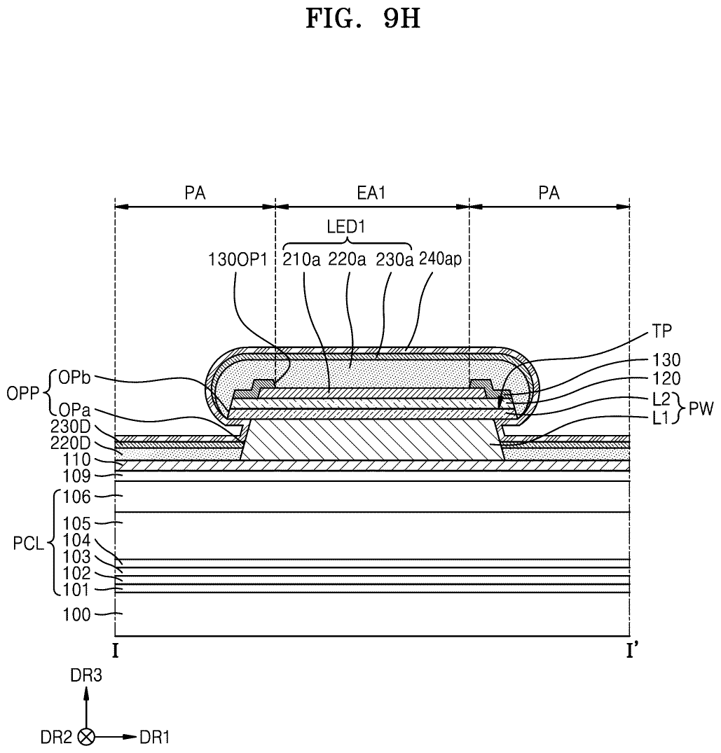

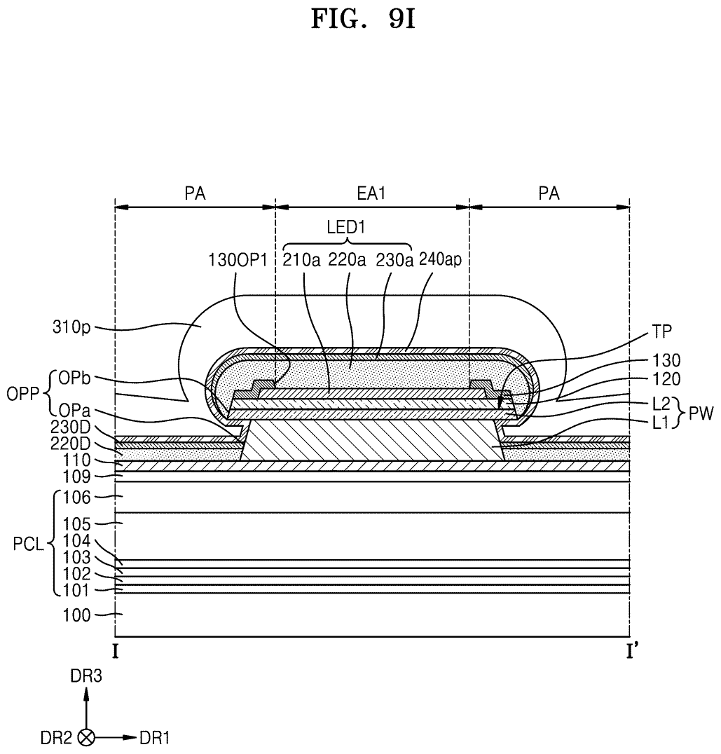

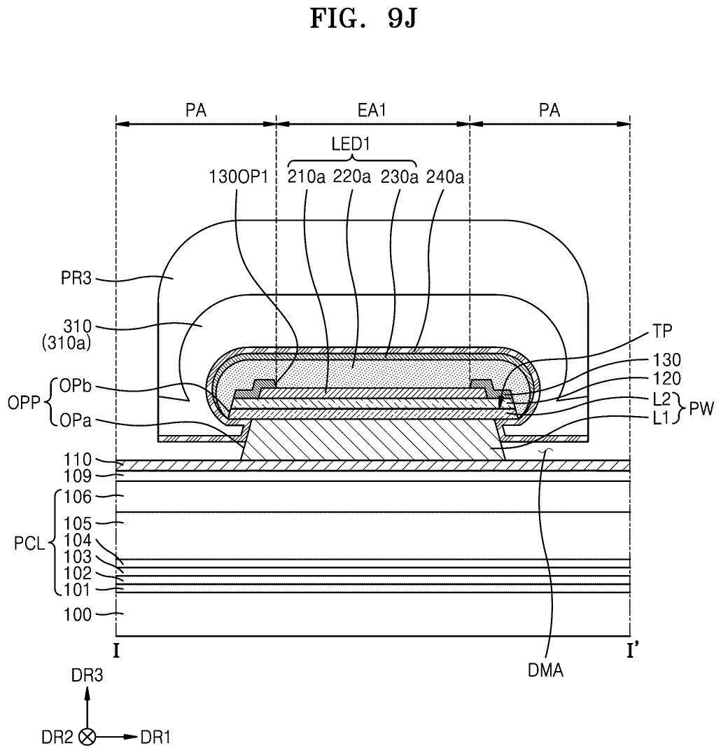

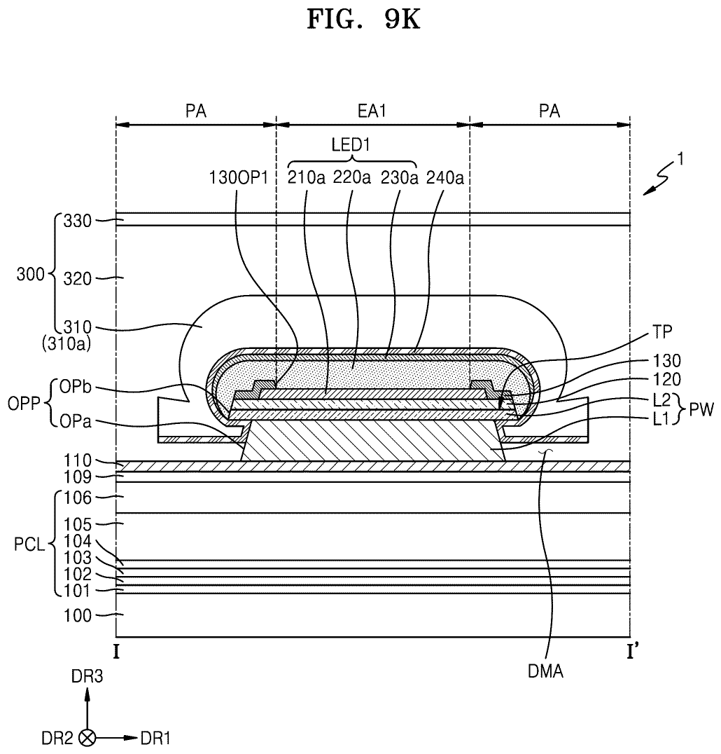

A portion of the first intermediate layer 220a may be disposed within the first pixel opening 130OP1 of the pixel defining layer 130, and another portion of the first intermediate layer 220a may be disposed outside the first pixel opening 130OP1 of the pixel defining layer 130. The first intermediate layer 220a may be disposed on the pixel defining layer 130. In an embodiment, the first intermediate layer 220a may cover an upper surface, inner surface, and outer surface of the pixel defining layer 130, for example. The first intermediate layer 220a may cover the side surface of the second partition wall layer L2. The first intermediate layer 220a may cover the side surface of the second partition wall layer L2 and a side surface of the partition wall insulation layer 120. Because the first intermediate layer 220a is physically separated from the dummy intermediate layer 220D by the tip portion TP of the conductive partition wall PW in the manufacturing process described with reference to FIG. 9F, the first intermediate layer 220a may be formed to cover the side surface of the second partition wall layer L2 of the conductive partition wall PW.

The first counter electrode 230a may be disposed on the first intermediate layer 220a. The first counter electrode 230a may cover the first intermediate layer 220a. In an embodiment, the first counter electrode 230a may cover an upper surface of the first intermediate layer 220a and a side surface of the first intermediate layer 220a, for example. The first counter electrode 230a may overlap the first pixel electrode 210a in an area corresponding to the first light-emitting area EA1, and may have an island-shaped pattern in a plan view. Because the first counter electrode 230a is physically separated from the dummy counter electrode 230D by the tip portion TP of the conductive partition wall PW in the manufacturing process described with reference to FIG. 9G, the first counter electrode 230a may be formed to cover the upper surface and side surface of the first intermediate layer 220a.

In an embodiment, the first counter electrode 230a may be provided as a transparent or semitransparent electrode. The first counter electrode 230a may include a conductive material having a relatively low work function. In an embodiment, the first counter electrode 230a may include a transparent layer (or semi-transparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloys thereof, for example. In an alternative embodiment, the first counter electrode 230a may further include a layer including such as ITO, IZO, ZnO or In₂O₃ on the transparent layer (or semi-transparent layer) including the aforementioned material. The first counter electrode 230a may be electrically connected to the conductive partition wall PW by the first auxiliary electrode 240a described below.

The first auxiliary electrode 240a may be disposed on the first counter electrode 230a. The first auxiliary electrode 240a may contact the first counter electrode 230a and the conductive partition wall PW to electrically connect the first counter electrode 230a and the conductive partition wall PW. The conductive partition wall PW may be electrically connected to the common electrode 110 and may receive the common voltage ELVSS (refer to FIG. 3), and the first counter electrode 230a may be electrically connected to the conductive partition wall PW and may receive the common voltage ELVSS (refer to FIG. 3).

In an embodiment, the first auxiliary electrode 240a may cover the first counter electrode 230a and cover at least a portion of the conductive partition wall PW. In an embodiment, the first auxiliary electrode 240a may cover a lower surface L2b of the second partition wall layer L2, for example. In an embodiment, the first auxiliary electrode 240a may contact the lower surface L2b of the second partition wall layer L2, for example. In an embodiment, the first auxiliary electrode 240a may cover the first counter electrode 230a and may extend along the lower surface L2b of the second partition wall layer L2 and a side surface L1s of the first partition wall layer L1, for example. In an embodiment, the first auxiliary electrode 240a may contact the side surface L1s of the first partition wall layer L1, for example. In an embodiment, the first auxiliary electrode 240a may include a portion covering the first counter electrode 230a, a portion extending along the lower surface L2b of the second partition wall layer L2 and the side surface Lis of the first partition wall layer L1 to contact the conductive partition wall PW, and a portion extending in the outward direction of the conductive partition wall PW from the portion contacting the conductive partition wall PW, for example.

The encapsulation layer 300 may be disposed on the first light-emitting element LED1 to encapsulate the first light-emitting element LED1. The encapsulation layer 300 may include an inorganic encapsulation pattern 310, an organic encapsulation layer 320, and an inorganic encapsulation layer 330.

The inorganic encapsulation pattern 310 may include a plurality of inorganic encapsulation patterns arranged to correspond to a plurality of light-emitting elements, respectively. In an embodiment, the inorganic encapsulation pattern 310 may include a first inorganic encapsulation pattern 310a disposed to correspond to (or overlap) the first light-emitting element LED1, for example. The first inorganic encapsulation pattern 310a may be disposed to correspond to (or overlap) the conductive partition wall PW. The first inorganic encapsulation pattern 310a may be disposed to correspond to (or overlap) the first light-emitting area EA1 of the first light-emitting element LED1. The first inorganic encapsulation pattern 310a may have an island-shaped pattern in a plan view. The first inorganic encapsulation pattern 310a may be disposed on the first auxiliary electrode 240a and cover an upper surface of the first auxiliary electrode 240a. In an embodiment, the first inorganic encapsulation pattern 310a may cover a portion of the upper surface of the first auxiliary electrode 240a covering the first counter electrode 230a and a portion of the upper surface of the first auxiliary electrode 240a in contact with the conductive partition wall PW, for example. In an embodiment, the first inorganic encapsulation pattern 310a may cover the upper surface of a part of the first auxiliary electrode 240a extending in the outward direction of the conductive partition wall PW from the portion of contacting the conductive partition wall PW, for example.

The inorganic encapsulation pattern 310 may include an inorganic material such as aluminum oxide, titanium oxide, tantalum oxide, hafnium oxide, zinc oxide, silicon oxide, silicon nitride, or silicon oxynitride, for example.

In FIG. 6, the inorganic encapsulation pattern 310 is illustrated as not being disposed in an area overlapping with the second portion 210p2 (refer to FIG. 4) of the first pixel electrode 210a of the first light-emitting element LED1, but this is merely one of embodiments and is not limited thereto. In another embodiment, the inorganic encapsulation pattern 310 may be disposed on an area overlapping a first portion 210p1 (refer to FIG. 4) of the first pixel electrode 210a and at least a portion of an area overlapping a second portion 210p2 (refer to FIG. 4) of the first pixel electrode 210a.

In the cross-sectional view, each of the first auxiliary electrode 240a and the inorganic encapsulation pattern 310 may be spaced apart from the common electrode 110. A space where the first auxiliary electrode 240a and the common electrode 110 are spaced apart may be defined as a dummy area DMA.

The organic encapsulation layer 320 may be disposed on the inorganic encapsulation pattern 310. The organic encapsulation layer 320 may cover the inorganic encapsulation pattern 310 and may provide a flat upper surface. A portion of the organic encapsulation layer 320 may fill the dummy area DMA. However, the shape of the organic encapsulation layer 320 is exemplary and is not limited to thereto. In an embodiment, the organic encapsulation layer 320 may not fill the dummy area DMA, and the dummy area DMA may remain as an empty space, for example.

The organic encapsulation layer 320 may include a polymer-based material. The polymer-based material may include acrylic resin, epoxy resin, polyimide, polyethylene, or the like.

The inorganic encapsulation layer 330 may be disposed on the organic encapsulation layer 320. The inorganic encapsulation layer 330 may include an inorganic material such as aluminum oxide, titanium oxide, tantalum oxide, hafnium oxide, zinc oxide, silicon oxide, silicon nitride, or silicon oxynitride, for example.

Referring to FIGS. 4 to 6 together, the first portion 210p1 of the first pixel electrode 210a may be a portion of overlapping with the first light-emitting area EA1, and the second portion 210p2 of the first pixel electrode 210a may be a portion that overlaps with the second contact hole CNT2, which is for connecting the first pixel electrode 210a to the connection electrode CM. The second contact hole CNT2 may be defined by penetrating the conductive partition wall PW, the common electrode 110, and the upper insulating layer 109, as illustrated in FIG. 6, and the first pixel electrode 210a may be electrically connected to the thin film transistor TFT through the second contact hole CNT2 and the connection electrode CM.

A display panel according to a comparative example includes a light-emitting element formed within a partition wall opening of a conductive partition wall (e.g., between inner surfaces of a plurality of conductive partition walls). In this case, during a deposition process of the light-emitting element, each layer of the light-emitting element is spaced apart from the inner surfaces of the conductive partition walls, and the light-emitting element (e.g., a counter electrode of the light-emitting element) is not electrically connected to the conductive partition wall.

In contrast, in an embodiment, because the first light-emitting element LED1 is formed on the conductive partition wall PW (e.g., an upper surface of the conductive partition wall PW) rather than inside the partition wall opening OPP of the conductive partition wall PW, a display panel 1 that is easy to implement a relatively high resolution may be provided by preventing or reducing the occurrence of poor electrical connection between the conductive partition wall PW and the first light-emitting element LED1. In addition, in an embodiment, because the first light-emitting element LED1 is not disposed inside the partition wall opening OPP of the conductive partition wall PW, a thickness of the conductive partition wall PW may be reduced.

FIG. 7 is a schematic cross-sectional view of a section of the display panel 1 taken along line III-III′ of FIG. 4. FIG. 7 illustrates an embodiment of a structure of the first subpixel P1, the second subpixel P2, and the third subpixel P3, in the cross-sectional view. Because, in the cross-sectional view, the structures of each of the first subpixel P1, the second subpixel P2, and the third subpixel P3 of FIG. 7 are substantially the same as or similar to the structure of the first subpixel P1 described with reference to FIG. 5, the description of the structure of the first subpixel P1 described with reference to FIG. 5 may also be applied to the structures of each of the first to third subpixels P1, P2, and P3.

Referring to FIG. 7, the display panel 1 may include a first light-emitting element LED1, a second light-emitting element LED2, and a third light-emitting element LED3. The plurality of conductive partition walls PW may be spaced apart from each other, and the conductive partition walls PW may overlap the first light-emitting element LED1, the second light-emitting element LED2, and the third light-emitting element LED3 in a direction perpendicular to the upper surface of the substrate 100 (e.g., the third direction DR3).

The partition wall insulation layer 120 may be disposed on each of the conductive partition walls PW. A first light-emitting element LED1, a second light-emitting element LED2, and a third light-emitting element LED3 may be disposed on the partition wall insulation layer 120.

The first light-emitting element LED1 may include a first pixel electrode 210a, a first intermediate layer 220a, and a first counter electrode 230a. The second light-emitting element LED2 may include a second pixel electrode 210b, a second intermediate layer 220b, and a second counter electrode 230b. The third light-emitting element LED3 may include a third pixel electrode 210c, a third intermediate layer 220c, and a third counter electrode 230c.

The first pixel electrode 210a, the second pixel electrode 210b, and the third pixel electrode 210c may be spaced apart from each other.

The first intermediate layer 220a, the second intermediate layer 220b, and the third intermediate layer 220c may be disposed on the first pixel electrode 210a, the second pixel electrode 210b, and the third pixel electrode 210c, respectively. The first intermediate layer 220a may emit light of a first color, the second intermediate layer 220b may emit light of a second color, and the third intermediate layer 220c may emit light of a third color.

The first counter electrode 230a, the second counter electrode 230b, and the third counter electrode 230c may be disposed on the first intermediate layer 220a, the second intermediate layer 220b, and the third intermediate layer 220c, respectively. The first counter electrode 230a, the second counter electrode 230b, and the third counter electrode 230c may be spaced apart from each other. In an embodiment, each of the first counter electrode 230a, the second counter electrode 230b, and the third counter electrode 230c may have an island-shaped pattern in a plan view, for example.

The pixel defining layer 130 may be disposed on each of the first pixel electrode 210a, the second pixel electrode 210b, and the third pixel electrode 210c. The pixel defining layer 130 may be disposed on the first pixel electrode 210a and may include a first pixel opening 130OP1 that exposes at least a portion of the first pixel electrode 210a. The pixel defining layer 130 may be disposed on the second pixel electrode 210b and may include a second pixel opening 130OP2 that exposes a portion of the second pixel electrode 210b. The pixel defining layer 130 may be disposed on the third pixel electrode 210c and may include a third pixel opening 130OP3 that exposes a portion of the third pixel electrode 210c.

The display panel 1 may include a first auxiliary electrode 240a, a second auxiliary electrode 240b, and a third auxiliary electrode 240c arranged to correspond to the first light-emitting element LED1, the second light-emitting element LED2, and the third light-emitting element LED3, respectively. The first auxiliary electrode 240a may be disposed on the first counter electrode 230a, the second auxiliary electrode 240b may be disposed on the second counter electrode 230b, and the third auxiliary electrode 240c may be disposed on the third counter electrode 230c. The first auxiliary electrode 240a, the second auxiliary electrode 240b, and the third auxiliary electrode 240c may be spaced apart from each other.

The first auxiliary electrode 240a may contact the first counter electrode 230a and the conductive partition wall PW to electrically connect the first counter electrode 230a and the conductive partition wall PW. The first counter electrode 230a may be electrically connected to the conductive partition wall PW and may receive the common voltage ELVSS (refer to FIG. 3). The second auxiliary electrode 240b may contact the second counter electrode 230b and the conductive partition wall PW to electrically connect the second counter electrode 230b and the conductive partition wall PW. The second counter electrode 230b may be electrically connected to the conductive partition wall PW and may receive the common voltage ELVSS (refer to FIG. 3). The third auxiliary electrode 240c may contact the third counter electrode 230c and the conductive partition wall PW to electrically connect the third counter electrode 230c and the conductive partition wall PW. The third counter electrode 230c may be electrically connected to the conductive partition wall PW and may receive the common voltage ELVSS (refer to FIG. 3).

In an embodiment, the first auxiliary electrode 240a may cover the first counter electrode 230a and cover at least a portion of the conductive partition wall PW corresponding to the first light-emitting element LED1. In an embodiment, the second auxiliary electrode 240b may cover the second counter electrode 230b and cover at least a portion of the conductive partition wall PW corresponding to the second light-emitting element LED2. In an embodiment, the third auxiliary electrode 240c may cover the third counter electrode 230c and cover at least a portion of the conductive partition wall PW corresponding to the third light-emitting element LED3.

The partition wall opening OPP may be defined as a space between the plurality of conductive partition walls PW. The partition wall opening OPP may not overlap with each of the first to third pixel electrodes 210a, 210b, and 210c. The partition wall opening OPP may overlap with a peripheral area PA surrounding the first to third light-emitting areas EA1, EA2, and EA3.

The first to third intermediate layers 220a, 220b, and 220c may be physically separated from the dummy intermediate layer 220D by the tip portion TP of the corresponding conductive partition wall PW in the manufacturing process described with reference to FIG. 9F, and thus may be formed to cover the side surface of the second partition wall layer L2 of the corresponding conductive partition wall PW.

The first to third counter electrodes 230a, 230b, and 230c may be physically separated from the dummy counter electrode 230D by the tip portion TP of the corresponding conductive partition wall PW in the manufacturing process described with reference to FIG. 9G, and thus may be formed to cover upper surfaces and side surfaces of the first to third intermediate layers 220a, 220b, and 220c, respectively.

In the case of a comparative example in which the first to third intermediate layers 220a, 220b, and 220c are patterned using a fine metal mask (FMM), a supporting spacer protruding from the conductive partition wall should be provided to support the fine metal mask. Additionally, because the fine metal mask is spaced apart from the base surface on which patterning is performed by the height of the partition walls or supporting spacers, implementing a high-resolution display panel may be limited. In addition, as the fine metal mask contacts the supporting spacer, foreign substances may remain on the supporting spacer after the patterning process of the first to third intermediate layers 220a, 220b, and 220c, or the supporting spacer may be damaged due to being impressed by the fine metal mask. Accordingly, a defective display panel may be formed in the comparative example.

According to the disclosure, the first to third intermediate layers 220a, 220b, and 220c may be patterned and deposited in sub-pixel units by the tip portion TP of the corresponding conductive partition wall PW. In an embodiment, unlike the comparative example, the display panel 1 in an embodiment may physically separate the first to third light-emitting elements LED1, LED2, and LED3 by the tip portion TP of the conductive partition wall PW without a fine metal mask that may contact the configuration within the display area DA (refer to FIG. 2), for example. Accordingly, current leakage or driving errors between first to third light-emitting areas EA1, EA2, and EA3 next (or adjacent) to each other may be prevented or reduced. Because patterning is possible even without providing the supporting spacer protruding from the conductive partition wall PW, the areas of the first to third light-emitting areas EA1, EA2, and EA3 may be miniaturized, thereby providing the display panel 1 that is easy to implement a relatively high resolution.

The encapsulation layer 300 may be disposed on the first to third light-emitting elements LED1, LED2, and LED3 to encapsulate the first to third light-emitting elements LED1, LED2, and LED3. The encapsulation layer 300 may include an inorganic encapsulation pattern 310, an organic encapsulation layer 320, and an inorganic encapsulation layer 330.

The inorganic encapsulation pattern 310 may include a plurality of inorganic encapsulation patterns, each arranged to correspond to the first to third light-emitting elements LED1, LED2, and LED3, respectively. In an embodiment, the inorganic encapsulation pattern 310 may include a first inorganic encapsulation pattern 310a disposed to correspond to (or overlap) the first light-emitting element LED1, a second inorganic encapsulation pattern 310b disposed to correspond to (or overlap) the second light-emitting element LED2, and a third inorganic encapsulation pattern 310c disposed to correspond to (or overlap) the third light-emitting element LED3, for example. The first inorganic encapsulation pattern 310a may cover the upper surface of the first auxiliary electrode 240a. The second inorganic encapsulation pattern 310b may cover an upper surface of the second auxiliary electrode 240b. The third inorganic encapsulation pattern 310c may cover an upper surface of the third auxiliary electrode 240c. The first to third inorganic encapsulation patterns 310a, 310b, and 310c may be arranged to overlap with the conductive partition walls PW, respectively. The first to third inorganic encapsulation patterns 310a, 310b, and 310c may be spaced apart from each other.

The organic encapsulation layer 320 may cover each of the first to third inorganic encapsulation patterns 310a, 310b, and 310c and may provide a flat upper surface. In an embodiment, the organic encapsulation layer 320 may be disposed entirely over the display area DA (refer to FIG. 2), for example. The inorganic encapsulation layer 330 may overlap with each of the first to third inorganic encapsulation patterns 310a, 310b, and 310c. In an embodiment, the inorganic encapsulation layer 330 may be disposed entirely over the display area DA (refer to FIG. 2), for example.

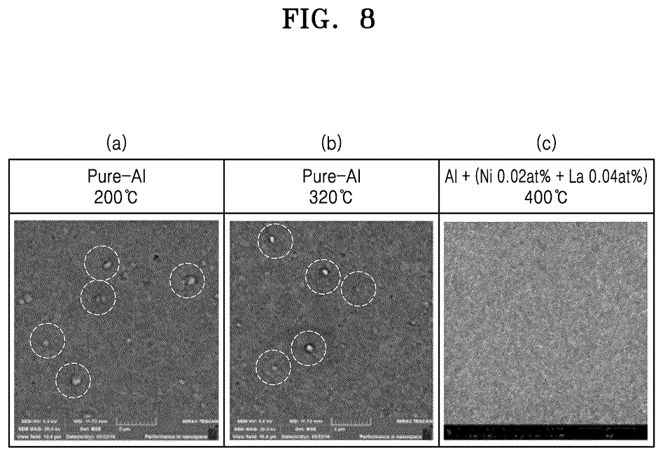

FIG. 8 illustrates a set of surface images of aluminum and aluminum alloy.

(a) of FIG. 8 is an image of the surface of an aluminum layer including or consisting of pure-aluminum (Al) taken with a scanning electron microscope (“SEM”) after heat treatment at 200 degrees Celsius (° C.). (b) of FIG. 8 is an image of the surface of an aluminum layer including or consisting of pure-aluminum (Al) taken with an SEM after heat treatment at 320° C. (c) of FIG. 8 is an image of the surface of an aluminum alloy layer including an aluminum-nickel-lanthanum alloy (Al—Ni—La alloy) including or consisting of aluminum as a main component and impurity metals of 0.02 at % nickel (Ni) and 0.04 at % lanthanum (La) based on total atoms in the aluminum-nickel-lanthanum alloy (Al—Ni—La alloy), taken with an SEM after heat treatment at 400° C.

Referring to (a) and (b) of FIG. 8, it may be seen that, a hillock defect occurs at a temperature of 200° C. or higher in the case of the aluminum layer including or consisting of pure-aluminum.

Referring to (c) of FIG. 8, it may be seen that in the case of the aluminum alloy layer including the aluminum alloy including or consisting of aluminum as a main component and the impurity metals of 0.06 at % or more, a hillock defect does not occur even at 400° C.

In an operation of forming the first to third pixel electrodes 210a, 210b, and 210c (refer to FIG. 7) of the display panel 1 (refer to FIG. 7), because the heat treatment of the first to third pixel electrodes 210a, 210b, and 210c (refer to FIG. 7) is performed at about 250° C., in a case of the first partition wall layer L1 (refer to FIG. 7) of the conductive partition wall PW (refer to FIG. 7) disposed below the first to third pixel electrodes 210a, 210b, and 210c (refer to FIG. 7) includes only pure-aluminum, a hillock defect may occur.

When the first partition wall layer L1 (refer to FIG. 7) of the conductive partition wall PW (refer to FIG. 7) includes an aluminum alloy as in an embodiment, a hillock defect does not occur even at 400° C., which is higher than 250° C., so that a display panel 1 with improved reliability may be provided.

FIGS. 9A to 9K are cross-sectional views illustrating a method of manufacturing the display panel 1. FIGS. 9A to 9K are cross-sectional views illustrating a method of manufacturing the display panel 1, the cross-sectional views corresponding to that of FIG. 5. In describing FIGS. 9A to 9K, the same or similar configurations are described with reference to FIGS. 4 to 7 using the same/similar reference numerals, and redundant descriptions will be omitted or simplified.

A method of manufacturing a display panel in an embodiment may include forming a pixel circuit layer and a common electrode on a substrate, forming a preliminary conductive partition wall including a first preliminary partition wall layer and a second preliminary partition wall layer on the common electrode, forming a preliminary partition wall insulation layer, a pixel electrode, and a preliminary pixel defining layer covering the pixel electrode on the preliminary conductive partition wall, etching the preliminary pixel defining layer to form a pixel opening overlapping the pixel electrode, etching the preliminary conductive partition wall, the preliminary partition wall insulation layer, and the preliminary pixel defining layer to form a conductive partition wall including a first partition wall layer and a second partition wall layer on the first partition wall layer, a partition wall insulation layer, and a pixel defining layer, forming an intermediate layer covering the pixel electrode on the conductive partition wall, and forming a counter electrode electrically connected to the conductive partition wall on the intermediate layer. The first partition wall layer may include an aluminum alloy, and the second partition wall layer may include a conductive material different from the first partition wall layer.

Referring to FIG. 9A, the method of manufacturing the display panel in an embodiment may include forming a pixel circuit layer PCL including a thin film transistor TFT (refer to FIG. 6) on the substrate 100 and forming a common electrode 110 on the pixel circuit layer PCL.

Next, the method of manufacturing the display panel in an embodiment may include forming a preliminary conductive partition wall PWP on the common electrode 110. The preliminary conductive partition wall PWP may include a first preliminary partition wall layer L1p disposed on a common electrode 110 and a second preliminary partition wall layer L2p disposed on the first preliminary partition wall layer L1p.

The first and second preliminary partition wall layers L1p and L2p may be formed by a deposition process of a conductive material.

In an embodiment, the first preliminary partition wall layer L1p may include an aluminum alloy. In an embodiment, the first preliminary partition wall layer L1p may include the aluminum alloy that includes aluminum (Al) as a main component and further includes at least one impurity metal selected from nickel (Ni), lanthanum (La), neodymium (Nd), or germanium (Ge), for example. In a case that the first preliminary partition wall layer L1p includes one impurity metal selected from nickel (Ni), lanthanum (La), neodymium (Nd), or germanium (Ge), an atomic ratio of the one impurity metal may be in a range of about 0.06 at % to about 1 at % based on total atoms in the aluminum alloy, and in a case that two or more impurity metals are selected from nickel (Ni), lanthanum (La), neodymium (Nd), or germanium (Ge), a sum of respective atomic ratios of two or more impurity metals selected from nickel (Ni), lanthanum (La), neodymium (Nd), or germanium (Ge) included in the aluminum alloy may be in a range of about 0.06 at % to about 1 at % based on total atoms in the aluminum alloy. In an embodiment, the first preliminary partition wall layer L1p may include an aluminum-nickel-lanthanum alloy (Al—Ni—La alloy), for example. In this case, in the aluminum-nickel-lanthanum alloy (Al—Ni—La alloy), a sum of atomic ratios of nickel (Ni) and lanthanum (La) may be in a range of about 0.06 at % to about 1 at % based on total atoms in the aluminum alloy.

The second preliminary partition wall layer L2p may include a different conductive material from the first preliminary partition wall layer L1p. In an embodiment, the second preliminary partition wall layer L2p may include gold (Au), magnesium (Mg), lithium (Li), molybdenum (Mo), titanium (Ti), copper (Cu), or an alloy, for example. In an embodiment, the second preliminary partition wall layer L2p may include a transparent conductive oxide such as ITO, IZO, zinc oxide, indium oxide, indium gallium oxide, IGZO, or aluminum zinc oxide, for example. In an embodiment, the second preliminary partition wall layer L2p may include the same material as that of the common electrode 110, but is not limited thereto.

Next, referring to FIG. 9B, the method of manufacturing the display panel in an embodiment may include forming a preliminary partition wall insulation layer 120p, a first pixel electrode 210a, and a preliminary pixel defining layer 130p covering the first pixel electrode 210a on the preliminary conductive partition wall PWP. A preliminary partition wall insulation layer 120p may be formed on the preliminary conductive partition wall PWP. The first pixel electrode 210a may be formed on the preliminary partition wall insulation layer 120p. When forming the first pixel electrode 210a, a heat treatment process may be performed at about 250° C. When the heat treatment process is performed on the first pixel electrode 210a, the first preliminary partition wall layer L1p of the preliminary conductive partition wall PWP disposed below the first pixel electrode 210a includes an aluminum alloy, so that hillock defects are prevented or reduced, and thus defects in the first pixel electrode 210a may be prevented or reduced. The preliminary pixel defining layer 130p may be formed by covering the first pixel electrode 210a.

The method of manufacturing the display panel in an embodiment may further include forming a first photoresist layer PR1 on the preliminary pixel defining layer 130p. The first photoresist layer PR1 may be formed by forming a preliminary photoresist layer on the preliminary pixel defining layer 130p and then patterning the preliminary photoresist layer using a photo mask. Through the patterning process, a first photo opening OP-PR1 overlapping the first pixel electrode 210a may be defined in the first photoresist layer PR1.

Next, referring to FIG. 9C, the method of manufacturing the display panel in an embodiment may include etching a preliminary pixel defining layer 130p to form a first pixel opening 130OP1 overlapping a first pixel electrode 210a.

The etching the preliminary pixel defining layer 130p may involve etching a portion of the preliminary pixel defining layer 130p using the first photoresist layer PR1 (refer to FIG. 9B) as a mask, and may be performed using dry etching. A portion of the preliminary pixel defining layer 130p may be removed by etching to form a first pixel opening 130OP1, and the first pixel opening 130OP1 may overlap the first pixel electrode 210a.

The method of manufacturing the display panel in an embodiment may further include forming a second photoresist layer PR2 on the preliminary pixel defining layer 130p after removing the first photoresist layer PR1. The second photoresist layer PR2 may be formed by forming a preliminary photoresist layer on a preliminary pixel defining layer 130p and then patterning the preliminary photoresist layer using a photo mask. Through the patterning process, the second photoresist layer PR2 may overlap the first pixel opening 130OP1.

Next, referring to FIGS. 9D and 9E, the method of manufacturing the display panel in an embodiment may include etching the preliminary conductive partition wall PWP (refer to FIG. 9C), the preliminary partition wall insulation layer 120p (refer to FIG. 9C), and the preliminary pixel defining layer 130p (refer to FIG. 9C) to form a conductive partition wall PW including a first partition wall layer L1 and a second partition wall layer L2 on the first partition wall layer L1, a partition wall insulation layer 120, and a pixel defining layer 130.

As illustrated in FIG. 9D, the second photoresist layer PR2 may be used as a mask to dry etch the preliminary conductive partition wall PWP (refer to FIG. 9C), the preliminary partition wall insulation layer 120p (refer to FIG. 9C), and the preliminary pixel defining layer 130p (refer to FIG. 9C). Portions of the preliminary conductive partition wall PWP (refer to FIG. 9C), the preliminary partition wall insulation layer 120p (refer to FIG. 9C), and the preliminary pixel defining layer 130p (refer to FIG. 9C) may be removed by dry etching, and a preliminary partition wall opening OPPa may be defined in the preliminary conductive partition wall PWP.

Next, as illustrated in FIG. 9D and FIG. 9E, the first preliminary partition wall layer L1p of the preliminary conductive partition wall PWP may be wet etched using the second photoresist layer PR2 as a mask. A portion of the first preliminary partition wall layer L1p may be removed by a wet etching process to form the first partition wall layer L1 and the second partition wall layer L2. The first partition wall layer L1 and the second partition wall layer L2 may be also referred to as a conductive partition wall PW. A partition wall opening OPP may be defined in the conductive partition wall PW. The partition wall opening OPP may include a first partition wall opening OPa defined by first partition wall layers L1 of the plurality of conductive partition walls PW and a second partition wall opening OPb defined by second partition wall layers L2 of the plurality of conductive partition walls PW.

In the illustrated embodiment, the etching selectivity of the first partition wall layer L1 and the second partition wall layer L2 may differ. Accordingly, a side surface of the conductive partition wall PW defining the partition wall opening OPP may have an undercut shape in the cross-sectional view. Specifically, because an etch rate of the first partition wall layer L1 is greater than that of the second partition wall layer L2, the first partition wall layer L1 may be primarily etched. Accordingly, the side surface of the first partition wall layer L1 may be recessed inwardly (e.g., toward the center of the conductive partition wall PW) more than the side surface of the second partition wall layer L2. A tip portion TP may be formed in the conductive partition wall PW by a portion of the second partition wall layer L2 that protrudes more than the first partition wall layer L1.

Next, the method of manufacturing the display panel in an embodiment may further include removing a second photoresist layer PR2 (refer to FIG. 9D).

Next, referring to FIG. 9F, the method of manufacturing the display panel according to the disclosure may forming a first intermediate layer 220a covering the first pixel electrode 210a on the conductive partition wall PW.

The forming the first intermediate layer 220a may include a deposition process of an emission layer. In an embodiment, the deposition process of the emission layer may be a thermal evaporation process. However, this is an illustrative embodiment and the deposition process of the emission layer is not limited to the above example. A material forming the first intermediate layer 220a may be separated by the tip portion TP formed in the conductive partition wall PW to form the first intermediate layer 220a and the dummy intermediate layer 220D. The dummy intermediate layer 220D may be formed simultaneously with the first intermediate layer 220a through a single process, and may be formed separately from the first intermediate layer 220a by the undercut shape of the conductive partition wall PW. That is, the first intermediate layer 220a and the dummy intermediate layer 220D may be formed in the same process and may include the same material as each other. In an embodiment, the dummy intermediate layer 220D may include the same material as a light-emitting material of the emission layer of the first intermediate layer 220a, for example.

The first intermediate layer 220a may be formed to cover a side surface of the partition wall insulation layer 120 and a side surface of the second partition wall layer L2, and the dummy intermediate layer 220D may be formed on the common electrode 110.

Next, referring to FIG. 9G, the method of manufacturing a display panel in an embodiment may include forming a first counter electrode 230a electrically connected to the conductive partition wall PW on the first intermediate layer 220a.

The forming the first counter electrode 230a may include a deposition process of the first counter electrode 230a. In an embodiment, the deposition process of the first counter electrode 230a may be a thermal evaporation process. However, this is an illustrative embodiment and the deposition process of the first counter electrode 230a is not limited to the above example. A material forming the first counter electrode 230a may be separated by the tip portion TP formed in the conductive partition wall PW to form the first counter electrode 230a and the dummy counter electrode 230D. The first counter electrode 230a may be formed to cover an upper surface of the first intermediate layer 220a and a side surface of the first intermediate layer 220a, and the dummy counter electrode 230D may be formed on the dummy intermediate layer 220D.

That is, in the forming the first counter electrode 230a, a dummy counter electrode 230D spaced apart from the first counter electrode 230a may be formed simultaneously. The dummy counter electrode 230D may include a conductive material. The dummy counter electrode 230D may be formed simultaneously with the first counter electrode 230a through a single process, and may be formed separately from the first counter electrode 230a by the undercut shape of the conductive partition wall PW. That is, the first counter electrode 230a and the dummy counter electrode 230D may be formed in the same process and may include the same material as each other.

The first pixel electrode 210a, the first intermediate layer 220a, and the first counter electrode 230a may be sequentially stacked along the third direction DR3. The first pixel electrode 210a, the first intermediate layer 220a, and the first counter electrode 230a may form a first light-emitting element LED1. The dummy intermediate layer 220D and the dummy counter electrode 230D may be sequentially stacked along the third direction DR3.

Next, referring to FIG. 9H, the method of manufacturing the display panel in an embodiment may include forming a first preliminary auxiliary electrode 240ap that covers the first counter electrode 230a and at least a portion of the conductive partition wall PW. The forming the first preliminary auxiliary electrode 240ap may include a deposition process of the first preliminary auxiliary electrode 240ap. The deposition process of the first preliminary auxiliary electrode 240ap may be a sputtering process. However, this is an illustrative embodiment and the deposition process of the first preliminary auxiliary electrode 240ap is not limited to the above example.

In an embodiment, the first preliminary auxiliary electrode 240ap may include a conductive material. In an embodiment, the conductive material may include a metal, a transparent conductive oxide (“TCO”), or any combinations thereof, for example. In an embodiment, the metal may include gold (Au), silver (Ag), aluminum (Al), magnesium (Mg), lithium (Li), molybdenum (Mo), titanium (Ti), copper (Cu), or an alloy. The transparent conductive oxide may include ITO, IZO, zinc oxide, indium oxide, indium gallium oxide, IGZO, or aluminum zinc oxide, for example.

The first preliminary auxiliary electrode 240ap may be formed on the first counter electrode 230a. In an embodiment, the first preliminary auxiliary electrode 240ap may be formed to cover the first counter electrode 230a and directly contact a lower surface of the second partition wall layer L2 to cover the lower surface of the second partition wall layer L2. In an embodiment, the first preliminary auxiliary electrode 240ap may be formed to extend along the lower surface of the second partition wall layer L2 and a side surface of the first partition wall layer L1. That is, the first preliminary auxiliary electrode 240ap may be formed by contacting the side surface of the first partition wall layer L1. In an embodiment, the first preliminary auxiliary electrode 240ap may be formed to contact the side surface of the first partition wall layer L1 and include a portion that protrudes from the side surface of the first partition wall layer L1 toward the outward direction of the conductive partition wall PW.

Next, referring to FIGS. 91 and 9J, the method of manufacturing the display panel in an embodiment may include forming a first auxiliary electrode 240a and a first inorganic encapsulation pattern 310a covering the first auxiliary electrode 240a. The forming the first auxiliary electrode 240a may include removing a portion of the first preliminary auxiliary electrode 240ap. The forming the first inorganic encapsulation pattern 310a may include depositing a preliminary inorganic encapsulation pattern 310p and removing a portion of the preliminary inorganic encapsulation pattern 310p that does not overlap with the first light-emitting element LED1.

Referring to FIG. 9I, the forming the first inorganic encapsulation pattern 310a may include the depositing a preliminary inorganic encapsulation pattern 310p. The preliminary inorganic encapsulation pattern 310p may be formed through a deposition process. In an embodiment, the preliminary inorganic encapsulation pattern 310p may be formed through a chemical vapor deposition (“CVD”) process. The preliminary inorganic encapsulation pattern 310p may be formed to cover an upper surface of the first preliminary auxiliary electrode 240ap.

Referring to FIG. 9J, the forming the first inorganic encapsulation pattern 310a may include forming a third photoresist layer PR3 and removing a portion of the preliminary inorganic encapsulation pattern 310p that does not overlap with the first light-emitting element LED1. The forming the first auxiliary electrode 240a may include removing a portion of the first preliminary auxiliary electrode 240ap.

In the forming the third photoresist layer PR3, the third photoresist layer PR3 may be formed by forming a preliminary photoresist layer and then patterning the preliminary photoresist layer using a photo mask. Through the patterning process, the third photoresist layer PR3 may be formed in a pattern shape corresponding to the first light-emitting element LED1.

The removing the portion of the preliminary inorganic encapsulation pattern 310p may be performed by dry etching the preliminary inorganic encapsulation pattern 310p using the third photoresist layer PR3 as a mask, so that the portion of the preliminary inorganic encapsulation pattern 310p that does not overlap with the first light-emitting element LED1 is removed. The portion of the preliminary inorganic encapsulation pattern 310p may be removed to form the first inorganic encapsulation pattern 310a that overlaps the first light-emitting element LED1.

The removing the portion of the first preliminary auxiliary electrode 240ap may be performed by etching the first preliminary auxiliary electrode 240ap using the third photoresist layer PR3 as a mask, so that the portion of the first preliminary auxiliary electrode 240ap that does not overlap with the first light-emitting element LED1 is removed. The portion of the first preliminary auxiliary electrode 240ap may be removed to form a first auxiliary electrode 240a that covers the first light-emitting element LED1 and at least a portion of the conductive partition wall PW.

The method of manufacturing the display panel in an embodiment may further include forming a dummy area DMA by removing the dummy intermediate layer 220D and the dummy counter electrode 230D. In an embodiment, the dummy counter electrode 230D may be removed by wet etching, and the dummy intermediate layer 220D may be removed by a stripper. At this time, the dummy intermediate layer 220D and the dummy counter electrode 230D may be removed to form a dummy area DMA between the conductive partition wall PW and the first inorganic encapsulation pattern 310a. As the dummy area DMA is formed, the first inorganic encapsulation pattern 310a may be formed spaced apart from the common electrode 110 in the cross-sectional view.

Next, referring to FIG. 9K, the method of manufacturing the display panel in an embodiment may include forming an organic encapsulation layer 320 and an inorganic encapsulation layer 330 after removing the third photoresist layer PR3 (refer to FIG. 9J). The organic encapsulation layer 320 may be formed by applying an organic material using an inkjet method, but is not limited thereto. The organic encapsulation layer 320 may provide a flat top surface. The organic encapsulation layer 320 may fill the dummy area DMA. However, this is merely one of embodiments and is not limited to the above examples. In an embodiment, the organic encapsulation layer 320 may not fill the dummy area DMA, or may only fill part of it, for example. The inorganic encapsulation layer 330 may be formed by depositing an inorganic material on the organic encapsulation layer 320.

In embodiments, the display panel and the electronic device including the same may include the light-emitting element disposed on the conductive partition wall, thereby providing a high-resolution display panel and an electronic device including the same.

In the display panel and an electronic device including the same in an embodiment, the conductive partition wall includes the first partition wall layer including an aluminum alloy, thereby preventing or reducing defects in the light-emitting element, thereby improving the reliability of the display panel and the electronic device including the same. The above-described effects are exemplary, and the scope of the disclosure is not limited by these effects.

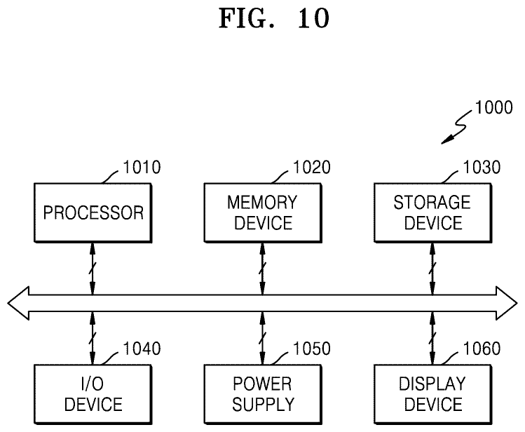

FIG. 10 is a block diagram illustrating an electronic device according to an embodiment.

Referring to FIG. 10, in an embodiment, an electronic device 1000 may include a processor 1010, a memory device 1020, a storage device 1030, an input/output (“I/O”) device 1040, a power supply 1050, and a display device 1060. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer, a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device 1000 may be implemented as a mobile phone, a video phone, a smart pad, a smart watch, a television, a tablet personal computer, a vehicle display, a computer monitor, a notebook computer, a head-mounted display device, etc. In addition, the electronic device 1000 may be a television, a monitor, a notebook computer, or a tablet. In addition, the electronic device 1000 may be a car.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display panel comprising:
a substrate;
a pixel circuit layer disposed on the substrate and including a transistor;
a common electrode disposed on the pixel circuit layer;
a conductive partition wall electrically connected to the common electrode, the conductive partition wall including:
a first partition wall layer disposed on the common electrode and including an aluminum alloy; and
a second partition wall layer disposed on the first partition wall layer;
a partition wall insulation layer disposed on the conductive partition wall; and
a light-emitting element including:
a pixel electrode, which is disposed on the partition wall insulation layer and electrically connected to the transistor;
an intermediate layer disposed on the pixel electrode and including an emission layer; and
a counter electrode disposed on the intermediate layer and electrically connected to the conductive partition wall.

2. The display panel of claim 1, wherein
the aluminum alloy includes aluminum (Al) as a main component and further includes at least one impurity metal selected from nickel (Ni), lanthanum (La), neodymium (Nd), or germanium (Ge).

3. The display panel of claim 2, wherein
in a state in which the at least one impurity metal is a singular impurity metal, an atomic ratio of the at least one impurity metal is in a range of about 0.06 atomic percent to about 1 atomic percent based on total atoms in the aluminum alloy, and
in a state in which the at least one impurity metal is provided in plural, a sum of respective atomic ratios of a plurality of impurity metals included in the aluminum alloy is in the range of about 0.06 atomic percent to about 1 atomic percent based on total atoms in the aluminum alloy.

4. The display panel of claim 1, wherein
the first partition wall layer includes an aluminum-nickel-lanthanum alloy (Al—Ni—La alloy).

5. The display panel of claim 4, wherein
a sum of an atomic ratio of nickel (Ni) and an atomic ratio of lanthanum (La) in the aluminum-nickel-lanthanum alloy (Al—Ni—La alloy) is in a range of about 0.06 atomic percent to about 1 atomic percent based on total atoms in the aluminum alloy.

6. The display panel of claim 1, wherein
the second partition wall layer includes a conductive material different from a conductive material of the first partition wall layer.

7. The display panel of claim 1, wherein
a width of the second partition wall layer in a first direction is greater than a width of the first partition wall layer in the first direction.

8. The display panel of claim 1, further comprising
a pixel defining layer which is disposed on the partition wall insulation layer and in which a pixel opening exposing at least a portion of the pixel electrode is defined.

9. The display panel of claim 8, wherein
the conductive partition wall overlaps the pixel opening.

10. The display panel of claim 1, wherein
the intermediate layer covers a side surface of the second partition wall layer, and the counter electrode covers an upper surface of the intermediate layer and a side surface of the intermediate layer.

11. The display panel of claim 1, further comprising
an auxiliary electrode covering the counter electrode and electrically connected to the conductive partition wall.

12. The display panel of claim 11, wherein
the auxiliary electrode covers at least a portion of the conductive partition wall.

13. The display panel of claim 12, wherein
the auxiliary electrode covers a lower surface of the second partition wall layer.

14. The display panel of claim 11, further comprising
an inorganic encapsulation pattern covering an upper surface of the auxiliary electrode,
wherein the inorganic encapsulation pattern is spaced apart from the common electrode in a cross-sectional view.

15. The display panel of claim 14, wherein
the inorganic encapsulation pattern has an island-shaped pattern in a plan view.

16. The display panel of claim 1, wherein
a distance from the substrate to the pixel electrode is greater than a distance from the substrate to the second partition wall layer.

17. A display panel comprising:
a conductive partition wall including:
a first partition wall layer including an aluminum alloy including:
aluminum (Al) as a main component; and
at least one impurity metal selected from nickel (Ni), lanthanum (La), neodymium (Nd), or germanium (Ge); and
a second partition wall layer disposed on the first partition wall layer and including a conductive material different from a conductive material of the first partition wall layer;
a light-emitting element including:
a pixel electrode disposed on the conductive partition wall and overlapping the conductive partition wall;
an intermediate layer disposed on the pixel electrode and including an emission layer; and
a counter electrode disposed on the intermediate layer and electrically connected to the conductive partition wall; and
a partition wall insulation layer disposed between the conductive partition wall and the light-emitting element.

18. The display panel of claim 17, wherein
in a state in which the at least one impurity metal is a singular impurity metal, an atomic ratio of the at least one impurity metal is in a range of about 0.06 atomic percent to about 1 atomic percent based on total atoms in the aluminum alloy, and
in a state in which the at least one impurity metal is provided in plural, a sum of respective atomic ratios of a plurality of impurity metals included in the aluminum alloy is in the range of about 0.06 atomic percent to about 1 atomic percent based on total atoms in the aluminum alloy.

19. The display panel of claim 17, wherein
the first partition wall layer includes an aluminum-nickel-lanthanum alloy (Al—Ni—La alloy).

20. An electronic device comprising:
a display panel,
a cover window disposed on the display panel; and
a housing accommodating the display panel and including a rear surface and a side surface;
wherein the display panel including:
a substrate;
a pixel circuit layer disposed on the substrate and including a transistor;
a common electrode disposed on the pixel circuit layer;
a conductive partition wall electrically connected to the common electrode, the conductive partition wall including:
a first partition wall layer disposed on the common electrode and including an aluminum alloy; and
a second partition wall layer disposed on the first partition wall layer;
a partition wall insulation layer disposed on the conductive partition wall; and
a light-emitting element including:
a pixel electrode disposed on the partition wall insulation layer and electrically connected to the transistor;
an intermediate layer disposed on the pixel electrode and including an emission layer; and
a counter electrode disposed on the intermediate layer and electrically connected to the conductive partition wall.
